(19) United States
(12) Patent Application Publication
(10) Pub. No.: US 2026/0332906 A1
(43) Pub. Date: Oct. 22, 2026

(54) IMAGE SENSOR AND OPERATING METHOD OF THE SAME

(71) Applicant: Samsung Electronics Co., Ltd., Suwon-si (KR)

(72) Inventor: Jinsuk HUH, Suwon-si (KR)

(73) Assignee: Samsung Electronics Co., Ltd., Suwon-si (KR)

(21) Appl. No.: 19/648,069

(22) Filed: Apr. 15, 2026

(30) Foreign Application Priority Data
Apr. 22, 2025 (KR) 10-2025-0052622

(51) Int. Cl. H04N 25/704; H04N 25/78

(52) U.S. Cl. CPC H04N 25/704; H04N 25/78

(57) ABSTRACT

An image sensor includes a pixel array including a first pixel and a second pixel in a same row. Each of the first pixel and the second pixel includes a first photodiode and a second photodiode, a floating diffusion region (FD) electrically connected to the first and the second photodiodes, a capacitor electrically connected to the FD, a dual conversion gain transistor connected between the FD and the capacitor, and a reset transistor configured to provide a power supply voltage to the FD and the capacitor, and a row driver configured to provide a first reset control signal to a first reset transistor of the first pixel through a first row line of row lines, and provide a second reset control signal to a second reset transistor of the second pixel through a second row line of the row lines.

### CROSS-REFERENCE TO RELATED APPLICATION

This U.S. non-provisional application claims priority under 35 U.S.C. § 119 to Korean Patent Application No. 10-2025-0052622, filed on Apr. 22, 2025, in the Korean Intellectual Property Office, the disclosure of which is incorporated herein by reference in its entirety.

### BACKGROUND

Example embodiments of the inventive concepts relate to an image sensor supporting an autofocus function and an operating method of the image sensor.

An image sensor is a device that captures a two-dimensional or three-dimensional image of an object. An image sensor generates an image of an object by using photoelectric conversion elements based on the intensity of light reflected from the object. It is beneficial to include image sensors having relatively higher performance in electronic devices, such as digital cameras, camcorders, personal communication systems (PCS), game consoles, surveillance cameras, medical micro cameras, and mobile phones.

### SUMMARY

Some example embodiments of the inventive concepts provide an image sensor and a method of operating the image sensor that includes an auto focus (AF) function in various operation modes.

Some example embodiments of the inventive concepts also provide an image sensor including an auto focus function to perform image capturing with improved accuracy within a relatively shorter period of time.

Accordingly, there are disclosed an image sensor and a method of operating the image sensor based on the example embodiments of the inventive concepts.

According to some example embodiments of the inventive concepts, an image sensor includes a pixel array including a first pixel and a second pixel in a same row. Each of the first pixel and the second pixel includes a first photodiode and a second photodiode, a floating diffusion region electrically connected to the first photodiode and the second photodiode, a capacitor electrically connected to the floating diffusion region, a dual conversion gain transistor connected between the floating diffusion region and the capacitor, and a reset transistor configured to provide a power supply voltage to the floating diffusion region and the capacitor, and a row driver configured to provide a plurality of control signals to the first pixel and the second pixel through a plurality of row lines, provide a first reset control signal to a first reset transistor of the first pixel through a first row line of the plurality of row lines, and provide a second reset control signal to a second reset transistor of the second pixel through a second row line of the plurality of row lines.

According to some example embodiments of the inventive concepts, an image sensor includes a pixel array including a plurality of pixel groups in a matrix, and each pixel group of the plurality of pixel groups includes a plurality of pixels in a matrix. Each pixel of the plurality of pixels includes a plurality of first photodiodes in a first region, a plurality of second photodiodes in a second region, a floating diffusion region electrically connected to the plurality of first photodiodes and the plurality of second photodiodes, a capacitor electrically connected to the floating diffusion region, and a reset transistor configured to provide a power supply voltage to the floating diffusion region and the capacitor. The image sensor further includes a row driver configured to provide a first reset control signal to a first reset transistor of a first pixel of the plurality of pixels, and provide a second reset control signal different from the first reset control signal to a second reset transistor of a second pixel that is in a same row as the first pixel.

According to some example embodiments of the inventive concepts, a method of operating an image sensor includes providing, during an exposure time, different reset control signals through a different control line to a first reset transistor included in a first pixel of the image sensor and a second reset transistor included in a second pixel of the image sensor. The first pixel and the second pixel are in a same row, and each of the first pixel and the second pixel includes a plurality of photodiodes in a matrix. The method further includes providing, during a readout time following the exposure time, a same reset control signal to the first reset transistor and the second reset transistor, and outputting a phase detection signal using the first pixel and outputting an image signal using the second pixel.

### BRIEF DESCRIPTION OF THE DRAWINGS

Example embodiments will be more clearly understood from the following description taken in conjunction with the accompanying drawings.

FIG. 1 is a block diagram schematically illustrating an image sensor according to some example embodiments.

FIGS. 2A and 2B are circuit diagrams showing pixels provided in an image sensor according to some example embodiments.

FIG. 3 illustrates a pixel array according to some example embodiments.

FIG. 4 is a circuit diagram illustrating a pixel array according to some example embodiments.

FIGS. 5A and 5B illustrate timing diagrams of a pixel array according to some example embodiments.

FIGS. 6A and 6B illustrate timing diagrams of a pixel array according to some example embodiments.

FIGS. 7A and 7B conceptually illustrate operations of autofocus pixels according to some example embodiments.

FIGS. 8A, 8B and 8C illustrate pixel arrays according to some example embodiments.

FIG. 9 illustrates connection relationships between row lines and transistors in a pixel array according to some example embodiments.

FIGS. 10A, 10B and 10C illustrate pixel arrays according to some example embodiments.

FIG. 11 illustrates a pixel array according to some example embodiments.

FIG. 12 illustrates a pixel array according to some example embodiments.

FIG. 13 is a flowchart illustrating an operation method of an image sensor according to some example embodiments.

FIGS. 14A and 14B illustrate a stack structure of an image sensor according to some example embodiments.

FIG. 15 is a block diagram illustrating an electronic device including an image sensor according to some example embodiments.

### DETAILED DESCRIPTION OF THE EXAMPLE EMBODIMENTS

Hereinafter, some example embodiments of the inventive concepts are described with reference to the attached drawings. Although the terms such as “first”, “second” may be used to describe various elements, regions, and/or portions, these terms are only used to distinguish one element, region, or portion from another element, region, or portion, and these terms do not imply a specific order, positional relationship, or hierarchical importance.

In the drawings, the thickness of layers, films, panels, regions, etc., are exaggerated for clarity.

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

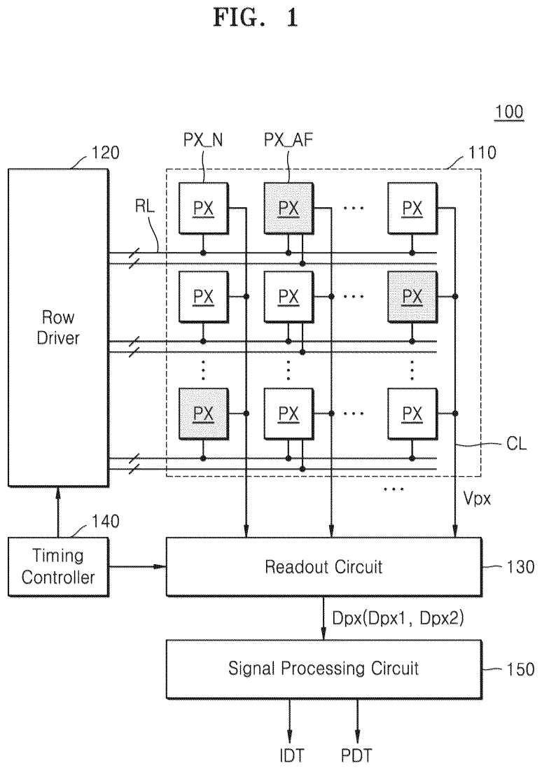

FIG. 1 is a block diagram schematically illustrating an image sensor according to some example embodiments.

An image sensor 100 may generate image data IDT based on a received optical signal (e.g., image information). The image sensor 100 may be mounted on or installed in an electronic device having an image or light sensing function. For example, the image sensor 100 may be mounted on electronic devices such as a camera, a smart phone, a wearable device, an Internet of Things (IoT), a tablet personal computer (PC), a personal digital assistant (PDA), a portable multimedia player (PMP), navigation, a drone, an advanced driver assistance system (ADAS), etc. In addition, the image sensor 100 may be mounted on electronic devices provided as components in vehicles, furniture, manufacturing equipment, doors, various measuring devices, etc.

Referring to FIG. 1, the image sensor 100 may include a pixel array 110, a row driver 120, a readout circuit 130, a timing controller 140, and a signal processing circuit 150. The image sensor 100 may further include other components, such as a voltage generator for generating various voltages (e.g., control voltages, bias voltages) used within the image sensor 100, and an interface circuit for transmitting the image data IDT to an external processor. The image sensor 100 may be implemented as a semiconductor chip or a semiconductor module.

The pixel array 110 may include a plurality of row lines RL, a plurality of column lines CL, and a plurality of pixels PX connected to the plurality of row lines RL and the plurality of column lines CL and arranged in a matrix. Multiple pixels (PX) may include active pixel sensors APS.

Each of the plurality of pixels PX is configured to detect (or sense) an optical signal (light) and generate an electrical signal (e.g., a pixel signal) corresponding to an intensity of the detected optical signal. Each of the plurality of pixels PX may include a plurality of photoelectric conversion elements, and the plurality of photoelectric conversion elements may share a floating diffusion region and a pixel circuit (e.g., a reset transistor, a select transistor, a source follower transistor, a dual conversion transistor, etc.). For example, the photoelectric conversion element may include a photodiode, an organic photodiode, a perovskite photodiode, a phototransistor, a photogate, or a pinned photodiode, or a combination thereof. Hereinafter, for the sake of discussion, a photodiode will be described as an example of the photoelectric conversion element. However, example embodiments are not limited to the use of a photodiode as the photoelectric conversion element.

One or more micro lenses may be placed on each pixel PX (e.g., on top of each pixel PX) for light collection. Each pixel PX may detect an optical signal in a specific or given spectral region from the optical signal received through (or using) the micro lens. For example, the pixel array 110 may include a red pixel for converting an optical signal in a red spectral region into an electrical signal, a green pixel for converting an optical signal in a green spectral region into an electrical signal, and a blue pixel for converting an optical signal in a blue spectral region into an electrical signal. However, example embodiments are not limited thereto, and the pixel array 110 may include pixels that convert optical signals in spectral regions other than red, green, and blue into electrical signals. For example, the pixel array 110 may include a red pixel, a green pixel, a blue pixel, and a white pixel, or the pixel array 110 may include a green pixel, a yellow pixel, and a cyan pixel.

A color filter array may be arranged on the pixel array 110 (e.g., on top of the pixel array 110). The color filter array is an arrangement of color filters arranged on top of each of the plurality of pixels PX to capture color information. Depending on a color of a color filter corresponding to each pixel PX of the pixel array 110, a color band (e.g., frequency band) detected by the pixel PX from received optical signals may be determined. The color filter array may have various color patterns, and accordingly, the pixel array 110 may have various color patterns. A single color filter of a color corresponding to each pixel PX may be arranged above a plurality of photodiodes of the pixel PX, or a plurality of color filters of an identical or similar color may be arranged above each of the plurality of photodiodes. In some example embodiments of the inventive concepts, the single color filter or the plurality of color filters individually arranged on top of the plurality of photodiodes is referred to as a unit color filter.

The plurality of pixels PX may receive pixel control signals through (or using) corresponding row lines RL among the plurality of row lines RL, generate a pixel signal Vpx in response to the pixel control signals, and output the pixel signal Vpx through (or using) the corresponding column line CL among the plurality of column lines CL.

The plurality of pixels PX may include a first pixel PX_AF and a second pixel PX_N. Here, the second pixel PX_N refers to a general pixel remaining among the plurality of pixels PX excluding one or more first pixels PX_AF. A plurality of first pixels PX_AF and a plurality of second pixels PX_N may be arranged in one row of the pixel array 110. In some example embodiments, the plurality of first pixels PX_AF and the plurality of second pixels PX_N may be arranged in each row of the pixel array 110. In some example embodiments, the plurality of first pixels PX_AF and the plurality of second pixels PX_N may be arranged in one or more rows of the pixel array 110, and the plurality of second pixels PX_N may be arranged in one or more other rows. The structures of the first pixel PX_AF and the second pixel PX_N may be similar, but the first pixel PX_AF and the second pixel PX_N may operate similar to each other or different from each other depending on the control signals received.

In a first operation mode of the image sensor 100, the first pixel PX_AF may generate phase detection signals used for phase difference detection for phase detection auto focus. The second pixel PX_N may generate an image signal including image information in the first operation mode. In the first operation mode, the first pixel PX_AF may operate as an auto focus pixel, and the second pixel PX_N may operate as a general pixel.

The first pixel PX1 may generate phase detection signals by erasing charges generated from one or more photodiodes arranged within a first region and generating a pixel signal corresponding to charges generated from one or more photodiodes arranged within a second region. The second pixel PX_N may generate image signals by generating pixel signals corresponding to charges generated from the photodiodes arranged within the first and second regions. In order for the first pixel PX_AF and the second pixel PX_N to operate differently, one or more pixel control signals (e.g., reset control signal, transfer control signal) provided to the first pixel PX_AF and the second pixel PX_N may be different from each other.

In a second operation mode of the image sensor 100, the first pixel PX_AF and the second pixel PX_N may perform identical or similar functions. For example, the first pixel PX_AF and the second pixel PX_N may each generate the image signal including image information. Alternatively, both the first pixel PX_AF and the second pixel PX_N may generate phase detection signals and image signals, respectively. The first pixel PX_AF and the second pixel PX_N may operate based on the same pixel control signal.

Below, the first operation mode of the image sensor 100 is described, and the first pixel PX_AF may be referred to as the auto focus pixel and the second pixel PX_N may be referred to as a normal pixel.

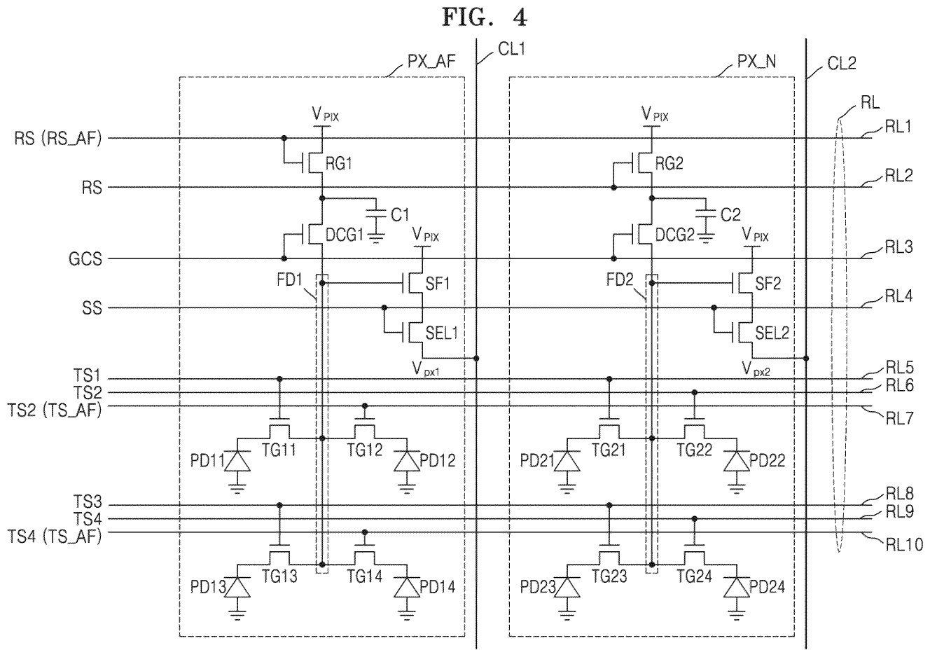

The auto focus pixels PX_AF and the normal pixels PX_N may be arranged in a same row and share one or more row lines RL. The auto focus pixel PX_AF may receive the pixel control signals for generating the phase detection signal through the separate row line RL. This will be described in detail later with reference to FIG. 4.

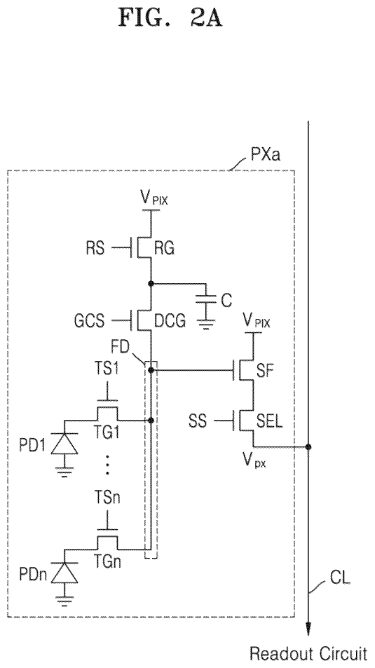

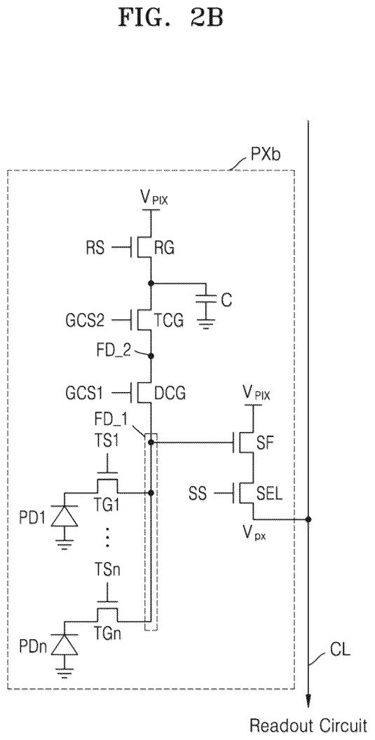

The row driver 120 may drive the pixel array 110. The row driver 120 may output the pixel control signals for driving the plurality of pixels PX to the pixel array 110. For example, the pixel control signals may include a reset control signal RS (of FIGS. 2A and 2B), a plurality of transfer control signals TS1 to TSn (of FIGS. 2A and 2B), a select signal SS (of FIGS. 2A and 2B), and a conversion gain control signal GCS (of FIGS. 2A and 2B). The row driver 120 may determine activation and deactivation timings of the pixel control signals based on various operation modes (e.g., the first operation mode, the second operation mode, etc.) of the image sensor 100.

The readout circuit 130 may convert a plurality of pixel signals Vpx (e.g., phase detection signals or image signals) received through the plurality of column lines CL into a plurality of pixel data Dpx. The readout circuit 130 may include a ramp signal generator and a plurality of analog-to-digital converters (ADCs), each corresponding to one or more of the plurality of column lines CL. The ramp signal generator may generate a ramp signal of which level increases or decreases at a constant slope, and each of the plurality of ADCs may compare the ramp signal received from the ramp signal generator with the pixel signal Vpx received through the corresponding column line CL, and generate the pixel data Dpx based on a comparison result.

Each of the plurality of ADCs may read out a reset level of the pixel signal Vpx and convert the reset level into a reset value according to a correlated double sampling (CDS) method, read out a signal level of the pixel signal Vpx and convert the signal level into a signal value, and remove (or lower or reduce) the reset value from the signal value to generate the pixel data Dpx (or referred to as the pixel value) representing an amount of light detected at the pixel PX. In some example embodiments, each of the plurality of ADCs may read out the signal level of the pixel signal Vpx and convert the signal level into the signal value according to a delta reset sampling (DRS) method, and then may read out the reset level of the pixel signal Vpx and convert the reset level into the reset value. In some example embodiments, the CDS method and the DRS method may be used together during the lead-out period.

In the first operation mode, a first pixel data Dpx1 corresponding to the auto focus pixel PX_AF may include phase information, and a second pixel data Dpx_N corresponding to the normal pixel PX_N may include image information (e.g., grayscale information).

The timing controller 140 may control overall operations of the image sensor 100. For example, the timing controller 140 may control operation timings of the image sensor 100 based on control information received from an external processor. For example, the timing controller 140 may provide control signals to control the operation timings of each of the row driver 120 and the readout circuit 130.

The signal processing circuit 150 may perform image processing or calculation processing on the plurality of pixel data Dpx, for example, a plurality of first pixel data Dpx1 and a plurality of second pixel data Dpx2, received from the readout circuit 130.

The signal processing circuit 150 may generate phase difference data PDT including phase difference information (e.g., disparity value) or first phase information and second phase information based on the plurality of first pixel data Dpx1.

The signal processing circuit 150 may perform the image processing on the image data IDT including a plurality of second pixel data Dpx_N. For example, the signal processing circuit 150 may change the data pattern of the image data IDT (e.g., change to an RGB pattern), or perform the image processing such as gain adjustment, binning, downsizing, remosaic, image quality compensation, and high dynamic range (HDR) processing on the image data IDT. Image quality compensation may include signal processing such as black level compensation (also called dark level compensation), lens shading compensation, crosstalk compensation, and bad pixel compensation, for example.

The phase data PDT and the image data IDT may be transmitted to an external processor. For example, the external processor may be a main processor of the electronic device on which the image sensor 100 is mounted or installed or otherwise operationally connected thereto. For example, the external processor may be an application processor of a mobile terminal.

The image sensor 100 may further include an interface circuit, and the interface circuit may transmit the phase data PDT and the image data IDT to an external processor according to a data communication method based on a set interface, for example, a mobile industry processor interface (MIPI).

FIGS. 2A and 2B are circuit diagrams showing pixels provided in an image sensor according to some example embodiments.

FIG. 2A shows a pixel PXa configured to operate in a dual conversion gain mode, and FIG. 2B shows a pixel PXb configured to operate in a triple conversion gain mode. The pixels PXa and PXb of FIGS. 2A and 2B may be the auto focus pixel PX_AF and the normal pixel PX_N of FIG. 1.

Referring to FIG. 2A, the pixel PXa may include a plurality of photodiodes, for example, a first to nth photodiodes PD1 to PDn (n is an integer of 2 or greater), a capacitor C, and a plurality of transistors, and the plurality of transistors may include a plurality of transfer transistors, for example, a first to nth transfer transistors TG1 to TGn (n is an integer of 2 or greater), a reset transistor RG, a dual conversion gain transistor DCG, a source follower transistor SF, and a select transistor SEL. The first to nth transfer transistors TG1 to TGn may be connected individually to corresponding one of the first to nth photodiodes PD1 to PDn. For example, the first transfer transistor TG1 may be connected to the first photodiode PD1, the second transfer transistor TG2 may be connected to the second photodiode PD2, and so forth. The reset transistor RG, the dual conversion gain transistor DCG, the source follower transistor SF, the select transistor SEL, and the capacitor C may operate as the pixel circuit. The capacitor C may be implemented as a capacitor capable of storing a relatively larger amount of charge, such as a metal-insulator-metal (MIM) capacitor or a dynamic random-access memory (DRAM) capacitor. A capacitance of the capacitor C may be greater than a capacitance of a floating diffusion region FD.

The first to nth transfer transistors TG1 to TGn, the reset transistor RG, the dual conversion gain transistor DCG, and the select transistor SEL may be turned on and off in response to the plurality of transfer control signals TS1 to TSn, the reset control signal RS, the conversion gain control signal GCS, and the select signal SS, respectively, which are provided through the row lines RL from the row driver (e.g., 120 of FIG. 1).

Each of the first to nth photodiodes PD1 to PDn may generate and store (integrate) charges depending on the intensity of the received light (optical signal). For example, each of the first to nth photodiodes PD1 to PDn may generate charges, i.e., electrons (negative charges) and holes (positive charges), in proportion to the amount of incident light. In some example embodiments, the first to nth photodiodes PD1 to PDn may be arranged in a matrix form, for example, arranged in a row by n columns, n rows by 1 column, k rows by 2 columns (where k is an integer greater than or equal to 2 and n is a positive integer multiple of k), or 2 rows by k columns, or arranged in a matrix form in m rows by m columns (where m is an integer greater than or equal to 2).

The first to nth transfer transistors TG1 to TGn may be connected to the floating diffusion region FD and corresponding photodiodes among the first to nth photodiodes PD1 to PDn. Each of the first to nth transfer transistors TG1 to TGn may be turned on in response to an on level of a corresponding transfer control signal among the transfer control signals TS1 to TSn to transfer charge integrated in a corresponding photodiode to the floating diffusion region FD. In some example embodiments of the inventive concepts, the on level (or referred to as an active level) represents a voltage level suitable for turning on a corresponding transistor, and an off level (or referred to as an inactive level) represents a voltage level suitable for turning off a corresponding transistor.

Depending on the operation mode of the image sensor 100 (of FIG. 1), the transfer control signals TS1 to TSn may be similar or different. For example, the transfer control signals TS1 to TSn may have the on levels in the same period or may have the on levels in different periods.

The floating diffusion region FD may store incoming charge. The floating diffusion region FD is a charge storage space formed by doping N-type impurities within a substrate, and may function like a capacitor that temporarily stores charge and generates a voltage proportional to the amount of charge stored. The rate at which charge stored in the floating diffusion region FD is converted to a voltage (e.g., voltage of the floating diffusion region FD) may be referred to as conversion gain.

The conversion gain may be varied depending on the capacitance of the floating diffusion region FD, and may be inversely proportional to the capacitance of the floating diffusion region FD. For example, as the capacitance of the floating diffusion region FD increases, the conversion gain may decrease, and as the capacitance of the floating diffusion region FD decreases, the conversion gain may increase.

The dual conversion gain transistor DCG may be turned on in response to the on level of the conversion gain control signal GCS to electrically connect the floating diffusion region FD to the capacitor C. As the floating diffusion region FD is connected to the capacitor C, the capacitance of the floating diffusion region FD increases, and the conversion gain may decrease. Therefore, a state in which the dual conversion gain transistor DCG is turned off may be referred to as a high conversion gain (HCG) mode, and a state in which the dual conversion gain transistor DCG is turned on may be referred to as a low conversion gain (LCG) mode.

The capacitor C may store the charges generated from the first to nth photodiodes PD1 to PDn. In some example embodiments, the capacitor C may store charge flowing in from the floating diffusion region FD as the dual conversion gain transistor DCG is turned on during a readout time (or readout period). In some example embodiments, the capacitor C may store charges overflowing from the first to nth photodiodes PD1 to PDn during an integration time (or exposure time) before the readout time. The image sensor 100 (of FIG. 1) may generate HDR image data by using the overflowed charges stored in the capacitor C in the first operation mode.

The reset transistor RG may be turned on in response to the on level of the reset control signal RS and may reset the floating diffusion region FD and the capacitor C. The reset transistor RG and the dual conversion gain transistor DCG may be turned on in response to the on levels of the reset control signal RS and the conversion gain control signal GCS, respectively, and a power supply voltage Vpix may be applied to the floating diffusion region FD and the capacitor C. Charges remaining in the floating diffusion region (FD) and the capacitor C may be removed (or lowered or reduced), and a voltage level (e.g., a reset level) of the floating diffusion region FD and of one end of the capacitor C may become equal to or similar to a voltage level of the power supply voltage Vpix.

The source follower transistor SF may buffer a voltage generated in the floating diffusion region FD (e.g., a potential of the floating diffusion region FD) and output the buffered voltage as the pixel signal Vpx. The select transistor SEL may be turned on in response to the on level of the select signal SS at the readout time of the pixel PX and may output the pixel signal Vpx generated by the source follower transistor SF. When the floating diffusion region FD is reset, a voltage of the reset level generated in the floating diffusion region FD may be output as the pixel signal Vpx, and also, when a charge provided from at least one of the first to nth photodiodes PD1 to PDn is stored in the floating diffusion region FD, a voltage of the signal level generated in the floating diffusion region FD may be output as the pixel signal Vpx.

In some example embodiments, the pixel PX used in the image sensor 100 may further include one or more conversion gain transistors (e.g., triple conversion gain transistors, etc.) connected to another node.

Referring to FIG. 2B, the pixel PXa may further include a triple conversion gain transistor TCG between the dual conversion gain transistor DCG and the reset transistor RG. The capacitor C may be connected to the reset transistor RG and the triple conversion gain transistor TCG. The dual conversion gain transistor DCG may be turned on and off in response to a first gain control signal GCS1, and the triple conversion gain transistor TCG can be turned on and off in response to a second gain control signal GCS2.

The dual conversion gain transistor DCG may be turned on in response to the on level of the first conversion gain control signal GCS1 to electrically connect a first floating diffusion region FD_1 and a second floating diffusion region FD_2. The first floating diffusion region FD_1 may correspond to the floating diffusion region FD of FIG. 2A, and the second floating diffusion region FD_2 may also be a charge storage space formed by doping impurities within the substrate.

The triple conversion gain transistor TCG may be turned on in response to the on level of a second conversion gain control signal GCS2 and may electrically connect the second floating diffusion region FD_2 to the capacitor C.

A state in which the dual conversion gain transistor DCG and the triple conversion gain transistor TCG are turned off may be referred to as the HCG mode, a state in which the dual conversion gain transistor DCG is turned on and the triple conversion gain transistor TCG is turned off may be referred to as a middle conversion gain (MCG) mode, and a state in which the dual conversion gain transistor DCG and the triple conversion gain transistor TCG are turned on may be referred to as the LCG mode.

In this way, the pixel PX used in the image sensor 100 (of FIG. 1) according to some example embodiments may operate in a plurality of conversion gain modes depending on the turn-on or turn-off state of a plurality of conversion gain transistors.

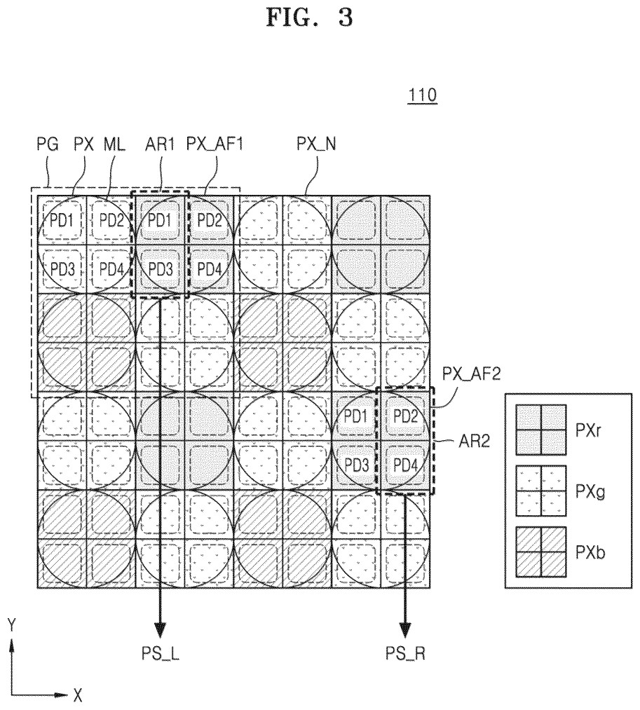

FIG. 3 illustrates a pixel array according to some example embodiments.

Referring to FIG. 3, the plurality of pixels PX may be arranged in a matrix on a plane of the pixel array 110 based on a first direction (e.g., X-axis direction or row direction) and a second direction (e.g., Y-axis direction or column direction). Each of the plurality of pixels PX may include the plurality of photodiodes (for example, four photodiodes PD1 to PD4), and one or more photodiodes (for example, first and third photodiodes PD1, PD3) among the plurality of photodiodes PD1 to PD4 may be arranged within a first region (a left region or an upper region) within the pixel PX, and the remaining photodiodes (for example, second and fourth photodiodes PD2, PD4) may be arranged within a second region (a right region or a lower region) within the pixel (PX). Here, the first region and the second region refer to the left region (or the upper region) and the right region (or the lower region), respectively, of a unit region in which the first to fourth photodiodes PD1 to PD4 of the pixel PX are formed on a plane of the substrate on which the plurality of photodiodes included in the pixel array 110 are formed.

One or more micro lenses ML may be arranged on the pixel PX. For example, within the pixel PX, the first and third photodiodes PD1 and PD3 may be arranged on the left, the second and fourth photodiodes PD2 and PD4 may be arranged on the right, and the micro lens ML may be arranged over the first to fourth photodiodes PD1 to PD4. In some example embodiments, the micro lens ML may be placed over the first and second photo diodes PD1 and PD2, and another micro lens ML may be placed over the third and fourth photo diodes PD3 and PD4.

The plurality of pixels PX may include red pixels PXr, green pixels PXg, and blue pixels PXb that are distinguished according to a color of an optical signal absorbed, and one red pixel PXr, one blue pixel PXb, and two green pixels PXg may be arranged in a 2×2 configuration to form a pixel group PG. The pixel group PG may be repeatedly arranged in the first direction and the second direction.

A color filter array having an extended Bayer pattern (e.g., a Quad Bayer pattern) structure may be disposed over the pixel array 110, and the pixel array 110 may generate the image data IDT (of FIG. 1) corresponding to the extended Bayer pattern or the image data IDT corresponding to the Bayer pattern, according to an operation mode.

The pixel array 110 may include a first auto focus pixel PX_AF1 and a second auto focus pixel PX_AF2. When the image sensor 100 operates in the first operation mode, the first auto focus pixel PX_AF1 may generate a first phase detection signal PS_L representing first phase information based on charges generated from photodiodes (e.g., the first and third photodiodes PD1 and PD3 of the first auto focus pixel PX_AF1) arranged within a first region AR1 (e.g., the left region), and the second auto focus pixel PX_AF2 may generate a second phase detection signal PS_R representing second phase information based on charges generated from photodiodes (e.g., the second and fourth photodiodes PD2 and PD4 of the second auto focus pixel PX_AF2) arranged within a second region AR2 (e.g., the right region). The image sensor 100 may generate the phase difference data PDT (of FIG. 1) based on the first phase detection signal PS_L and the second phase detection signal PS_R.

The normal pixels PX_N, excluding the first auto focus pixel PX_AF1 and the second auto focus pixel PX_AF2, store overflow charges in a capacitor (e.g., C2 in FIG. 4) during an integration time, and HDR image data may be generated by using the overflow charges stored in the capacitor.

When utilizing the overflow charges stored in the capacitor, charges generated from the photodiodes placed in the first region AR1 of a pixel (PX) and charges generated from the photodiodes placed in the second region AR2 may be mixed in the floating diffusion region and the capacitor, which may cause the phase information to be lost. Therefore, the first auto focus pixel PX_AF1 and the second auto focus pixel PX_AF2 according to some example embodiments may remove (or lower or reduce) the charges generated in the photodiodes disposed in one of the first region AR1 and the second region AR2 during the integration time, and generate a phase information signal by using charges generated in the photodiodes disposed in the other region during the readout time. The first auto focus pixel PX_AF1 may remove (or lower or reduce) the charges generated from the photodiodes disposed in the second region AR2, and the second auto focus pixel PX_AF2 may remove (or lower or reduce) the charges generated from the photodiodes disposed in the first region AR1. The first auto focus pixel PX_AF1 and the second auto focus pixel PX_AF2 may operate differently from the normal pixels PX_N based on control signals that are different from the control signals provided to the normal pixels PX_N arranged in the same row.

FIG. 4 is a circuit diagram illustrating the pixel array 110 according to some example embodiments.

Referring to FIG. 4, the pixel array 110 may include the auto focus pixels PX_AF and the normal pixels PX_N. The pixel PXa described with reference to FIG. 2A is described by way of example as being applied to or configured as the auto focus pixel PX_AF and the normal pixel PX_N. However, example embodiments are not limited thereto, and the pixel PXb of FIG. 2B or a pixel of another structure may be applied to or configured as the auto focus pixel PX_AF and the normal pixel PX_N.

Referring to FIG. 4, the auto focus pixel PX_AF may include first to fourth photodiodes PD11 to PD14, first to fourth transfer transistors TG11 to TG14, a reset transistor RG1, a dual conversion gain transistor DCG1, a source follower transistor SF1, a select transistor SEL1, and a capacitor C1. The normal pixel PX_N may include first to fourth photodiodes PD21 to PD24, first to fourth transfer transistors TG21 to TG24, a reset transistor RG2, a dual conversion gain transistor DCG2, a source follower transistor SF2, a select transistor SEL2, and the capacitor C2. In some example embodiments, for convenience of explanation, the auto focus pixel PX_AF and the normal pixel PX_N are illustrated as including four photodiodes PD11 to PD14 and PD21 to PD24 and four transfer transistors TG11 to TG14 and TG21 to TG24, respectively, but are not limited thereto, and the number of photodiodes and the number of transfer transistors may be changed, and the number of transfer transistors may be same as the number of photodiodes.

In each of the auto focus pixels PX_AF and the normal pixels PX_N, the first to fourth photodiodes PD11 to PD14 and PD21 to PD24 may be arranged in a matrix as shown in FIG. 3. For example, in each of the auto focus pixels PX_AF and the normal pixels PX_N, the first and third photodiodes PD11 and PD13, and PD21 and PD23 may be arranged within the first region (e.g., the left region or the upper region) within each pixel, and the second and fourth photodiodes PD12 and PD14, and PD22 and PD24 may be arranged within the second region (e.g., the right region or the lower region) within the pixel. One or more micro lenses (ML) may be arranged over the first to fourth photo diodes PD11 to PD14, and PD21 to PD24, and one or more photo diodes arranged within the first region and one or more photo diodes arranged within the second region may share one micro lens ML.

One or more transistors of the auto focus pixel PX_AF and the normal pixel PX_N may be connected to the same row line to receive a pixel control signal through the same row line, and the other one or more transistors may be connected to different row lines to receive a pixel control signal through different row lines.

In some example embodiments, in the second operation mode of the image sensor 100 (of FIG. 1), transistors performing the identical function in the auto focus pixel PX_AF and the normal pixel PX_N may receive a same pixel control signal through the same or different row lines. For example, the reset transistors RG1 and RG2 of the auto focus pixel PX_AF and the normal pixel PX_N may receive the reset control signal RS through a first row line RL1 and a second row line RL2, respectively, and the dual conversion gain transistors DCG1 and DCG2 of the auto focus pixel PX_AF and the normal pixel PX_N may receive the conversion gain control signal GCS through a third row line RL3. The first transfer transistors TG11 and TG21 of the auto focus pixel PX_AF and the normal pixel PX_N may receive the transfer control signal TS1 through a fifth row line RL5, and the second transfer transistors TG12 and TG22 of the auto focus pixel (PX_AF) and the normal pixel PX_N may receive the transfer control signal TS2 through a sixth row line RL6 and a seventh row line RL7, respectively.

In the second operation mode, the auto focus pixel PX_AF and the normal pixel PX_N may operate identically based on the same pixel control signals. The auto focus pixel PX_AF and the normal pixel PX_N may output a first pixel signal Vpx1 and a second pixel signal Vpx2, respectively, and the first pixel signal Vpx1 and the second pixel signal Vpx2 may include image information or phase information.

In some example embodiments, in the first operation mode of the image sensor 100, one or more of the transistors performing the identical function in the auto focus pixel PX_AF and the normal pixel PX_N may receive the same pixel control signal through the same row line, and the other one or more transistors may receive different pixel control signals through different row lines.

For example, the reset transistor RG1 of the auto focus pixel PX_AF may receive a reset control signal RS_AF for auto focus (hereinafter referred to as an AF reset control signal) through the first row line RL1, and the reset transistor RG2 of the normal pixel PX_N may receive the reset control signal RS through the second row line RL2. The dual conversion gain transistors DCG1 and DCG2 of the auto focus pixel PX_AF and the normal pixel PX_N may receive a conversion gain control signal GCS through the third row line RL3, and the select transistors SEL1 and SEL2 may receive the select signal SS through a fourth row line RL4.

The first transfer transistors TG11 and TG21 of the auto focus pixel PX_AF and the normal pixel PX_N may receive the transfer control signal TS1 through the fifth row line RL5, and third transfer transistors TG13 and TG23 may receive a transfer control signal TS3 through an eighth row line RL8.

The second transfer transistor TG12 of the auto focus pixel PX_AF may receive a transfer control signal TS_AF for auto focus (hereinafter referred to as an AF transfer control signal) through the seventh row line RL7, and the second transfer transistor TG22 of the normal pixel PX_N may receive the transfer control signal TS2 through the sixth row line RL6.

The fourth transfer transistor TG14 of the auto focus pixel PX_AF may receive the AF transfer control signal TS_AF through a tenth row line RL10, and the fourth transfer transistor TG24 of the normal pixel PX_N may receive the transfer control signal TS4 through a ninth row line RL9.

In this way, in the first operation mode, the reset transistor RG1, the second transfer transistor TG12, and the fourth transfer transistor TG14 of the auto focus pixel PX_AF may receive the control signals for auto focus (e.g., the AF reset control signal, the AF transfer control signal) through row lines separate from the row lines connected to the normal pixel PX_N, respectively. The auto focus pixel PX_AF and the normal pixel PX_N may operate differently based on the same or different pixel control signals received. In the first operation mode, the first pixel signal Vpx1 output from the auto focus pixel PX_AF may include phase information, and a second pixel signal Vpx2 output from the normal pixel PX_N may include image information.

The auto focus pixel PX_AF of FIG. 4 may correspond to the first auto focus pixel PX_AF1 of FIG. 3. The structure of the second auto focus pixel PX_AF2 of FIG. 3 may be similar to the structure of the auto focus pixel PX_AF, and the first and third transfer transistors TG11 and TG13 may receive the transfer control signals through different row lines from the first and third transfer transistors TG21 and TG23 of the normal pixel PX_N, and the second and fourth transfer transistors TG12 and TG14 may receive transfer control signals through the same row lines as the second and fourth transfer transistors TG22 and TG24 of the normal pixel PX_N.

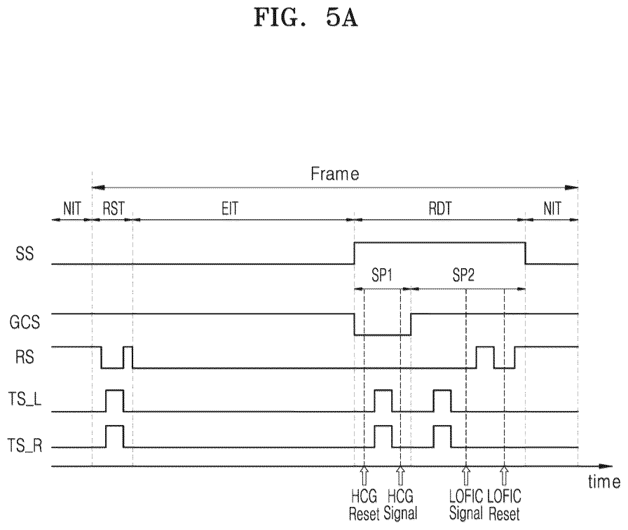

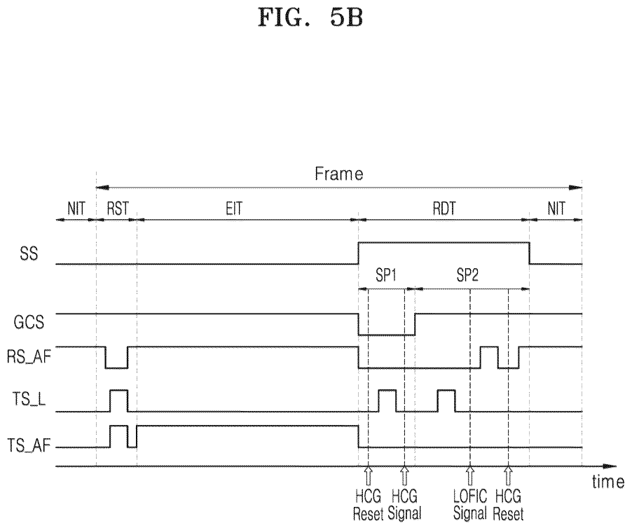

FIGS. 5A and 5B illustrate timing diagrams of a pixel array according to some example embodiments.

FIG. 5A is a timing diagram of the normal pixel PX_N (of FIG. 4) when the image sensor 100 is in the first operation mode, and FIG. 5B is a timing diagram of the auto focus pixel PX_AF (of FIG. 4) when the image sensor 100 is in the first operation mode. In FIGS. 5A and 5B, the high level of each of the select signal SS, the conversion gain control signal GCS, the reset control signal RS, the AF reset control signal RS_AF, a first transfer control signal TS_L, a second transfer control signal TS_R, and the AF transfer control signal TS_AF may indicate the on level (active level), and the low level may indicate the off level (inactive level).

Referring to FIGS. 5A and 5B, a frame may include a reset time RST, an integration time EIT, a readout time RDT, and may further include a non-integration time NIT from after the readout time RDT to before the reset time RST of a subsequent frame, or from after the readout time RDT of the previous frame to before the reset time RST. During the reset time RST, any remaining charges in the photodiodes (e.g., charges generated in the photodiodes during the non-integration time NIT) may be removed (or lowered or reduced). Charges may be integrated in the photodiodes during the integration time EIT, and the reset level and signal level of the pixel may be read out during the readout time RDT.

The operation of the normal pixel PX_N in the first operation mode is described with reference to FIGS. 4 and 5A. At the reset time RST, the select transistor SEL2 may be turned off in response to the off level of the select signal SS, and the plurality of transfer transistors TG21 to TG24 may be turned on in response to the on levels of the first transfer control signal TS_L and the second transfer control signal TS_R. Here, the first transfer control signal TS_L may be commonly provided to the transfer transistors (e.g., the first and third transfer transistors TG21 and TG23) connected to the photodiodes (e.g., the first and third photodiodes PD21 and PD23) positioned in the first region (e.g., the left region) of the normal pixel PX_N, and the second transfer control signal TS_R may be commonly provided to the transfer transistors (e.g., the second and fourth transfer transistors TG22 and TG24) connected to the photodiodes (e.g., the second and fourth photodiodes PD22 and PD24) positioned in the second region (e.g., the right region) of the normal pixel PX_N.

Charges remaining in the first to fourth photodiodes PD21 to PD24 are transferred to a floating diffusion region FD2, and then the reset transistor RG2 may be turned on in response to the on level of the reset control signal RS, and the floating diffusion region FD2 may be reset. Accordingly, the charges remaining in the first to fourth photodiodes PD21 to PD24 may be removed (or lowered or reduced). The process of removing the remaining charges in the plurality of photodiodes PD21 to PD24 by turning on a plurality of transfer transistors TG21 to TG24 at the reset time RST may be referred to as shuttering.

In FIG. 5A, the reset control signal RS is illustrated as having the off level when the first transfer control signal TS_L and the second transfer control signal TS_R are at the on level, but is not limited thereto, and in some example embodiments, the reset control signal RS may have the on level. The conversion gain control signal GCS may have the on level or be identical to the reset control signal RS.

During the integration time EIT, the select signal SS, the reset control signal RS, the first transfer control signal TS_L and the second transfer control signal TS_R may be at the off level, and the conversion gain control signal GCS may be at the on level. The reset transistor RG2 and the first to fourth transfer transistors TG21 to TG24 may be turned off, and the dual conversion gain transistor DCG2 may be turned on. During the integration time EIT, each of the first to fourth photodiodes PD21 to PD24 may generate and store charges based on an intensity of a received optical signal. When the intensity of the optical signal is large, an amount of charges greater than an amount that can be stored by each of the first to fourth photodiodes PD21 to PD24 may be generated, and the excess charges may overflow into the floating diffusion region FD2. Because the dual conversion gain transistor DCG2 is in a turned-on state, the overflowed charges may be stored in the capacitor C2.

The select signal SS may be at the on level during the readout time RDT. The conversion gain control signal GCS may have the off level during a first sub-period SP1 of the readout time RDT and the on level during a second sub-period SP2. In response to the off level of the conversion gain control signal GCS during the first sub-period SP1 of the readout time RDT, the dual conversion gain transistor DCG2 may be turned off, and the normal pixel PX_N may operate in the HCG mode. In the HCG mode, the reset level (HCG Reset) of the floating diffusion region FD2 may be read out before the first transfer control signal TS_L and the second transfer control signal TS_R transition from the off level to the on level. In the inventive concept, the reset level or signal level being read out means that the pixel signal corresponding to the reset level or signal level may be output and converted into the reset value or signal value in the readout circuit 130 (of FIG. 1).

When the first transfer control signal TS_L and the second transfer control signal TS_R transition from the off level to the on level, the first to fourth transfer transistors TG21 to TG24 may be turned on in response to the on level of the first transfer control signal TS_L and the second transfer control signal TS_R, and the charges stored in the first to fourth photodiodes PD21 to PD24 may be transferred to the floating diffusion region FD2 and stored in the floating diffusion region FD2. Thereafter, in response to the off levels of the first transfer control signal TS_L and the second transfer control signal TS_R, the first to fourth transfer transistors TG21 to TG24 may be turned off and the signal level (HCG Signal) of the floating diffusion region FD2 may be read out. The readout circuit 130 (of FIG. 1) may generate HCG pixel data representing image information based on the reset level and the signal level read out in the HCG mode.

In response to the on level of the conversion gain control signal GCS during the second sub-period SP2 of the readout time RDT, the dual conversion gain transistor DCG2 may be turned on, and the normal pixel PX_N may operate in a lateral overflow integration capacitor (LOFIC) mode. In the LOFIC mode, the capacitor C2 may be electrically connected to the floating diffusion region FD2. Therefore, the conversion gain in the LOFIC mode may be lower than that in the HCG mode, and the LOFIC mode may mean the LCG mode.

In response to the on levels of the first transfer control signal TS_L and the second transfer control signal TS_R, the first transfer control signal TS_L and the second transfer control signal TS_R may be turned on, and the charges remaining in the first to fourth photodiodes PD21 to PD24 and newly generated charges may be transferred to the floating diffusion region FD2 and stored in the floating diffusion region FD2 and the capacitor C2. Here, the newly generated charge may refer to charge generated in the first to fourth photodiodes PD21 to PD24 after the first transfer control signal TS_L and the second transfer control signal TS_R are turned off in the HCG mode, until the first transfer control signal TS_L and the second transfer control signal TS_R are turned on again in the LOFIC mode. After the first to fourth transfer transistors TG21 to TG24 are turned off in response to the off levels of the first transfer control signal TS_L and the second transfer control signal TS_R, a signal level (LOFIC Signal) of the floating diffusion region FD2 may be read out. A voltage corresponding to the charge stored in the floating diffusion region FD2 and capacitor C2 may be read out.

Afterwards, the reset control signal RS may transition from the off level to the on level. In response to the on level of the reset control signal RS, the reset transistor RS2 may be turned on, and the floating diffusion region FD2 and capacitor C2 may be reset. The charges stored in the floating diffusion region FD2 and capacitor C2 may be removed (or lowered or reduced).

After the reset control signal RS transitions from the on level to the off level and the reset transistor RS2 is turned off in response to the off level of the reset control signal RS, the reset level (LOFIC Reset) of the floating diffusion region FD2 may be read out.

The readout circuit 130 (of FIG. 1) may generate LCG pixel data representing image information based on the reset level and signal level read out in the LOFIC mode. A signal processing circuit 150 of FIG. 1 (or an external processor) may generate HDR image data based on the HCG image data, which includes a plurality of HCG pixel data generated in the HCG mode, and the LCG image data, which includes a plurality of LCG pixel data generated in the LOFIC mode. Luminance of the LCG image data is different from luminance of the HCG image data. For example, the luminance of the LCG image data may be higher than the luminance of the HCG image data. The signal processing circuit 150 may generate HDR image data by merging the HCG image data and the LCG image data.

The operation of the auto focus pixel PX_AF in the first operation mode is described with reference to FIGS. 4 and 5B. In FIG. 5B, the reset time RST, the integration time EIT, the readout time RDT, and the non-integration time NIT may represent times similar to the reset time RST, the integration time EIT, the readout time RDT, and the non-integration time NIT of FIG. 5A.

The select signal SS and the conversion gain control signal GCS applied to the select transistor SEL1 and the dual conversion gain transistor DCG1, respectively, may be similar to the select signal SS and the conversion gain control signal GCS of FIG. 5A. Additionally, the first transfer control signal TS_L applied to the transfer transistors (e.g., the first and third transfer transistors TG11 and TG13) connected to the photodiodes (e.g., the first and third photodiodes PD11 and PD13) arranged within the first region (e.g., the left region) of the auto focus pixel PX_AF may be similar to the first transfer control signal TS_L of FIG. 5A. The select transistor SEL1, the dual conversion gain transistor DCG1, and the first and third transfer transistors TG11 and TG13 of the auto focus pixel PX_AF may operate identically to the select transistor SEL2, the dual conversion gain transistor DCG2, and the first and third transfer transistors TG21 and TG23 of the normal pixel PX_N.

The reset transistor RG1 may operate in response to the AF reset control signal RS_AF, and the transfer transistors (e.g., the second and fourth transfer transistors TG12 and TG14) connected to the photodiodes (e.g., the second and fourth photodiodes PD12 and PD14) arranged within the second region (e.g., the right region) of the auto focus pixel PX_AF may operate in response to the AF transfer control signal TG_AF. The AF reset control signal RS_AF and the AF transfer control signal TG_AF and the reset control signal RS and the second transfer control signal TS_R of FIG. 5A may be similar during the reset time RST and different during the integration time EIT and the readout time RDT.

The auto focus pixel PX_AF may operate identical or similar to the normal pixel PX_N during the reset time RST. The remaining charges in the first to fourth photodiodes PD11 to PD14 may be removed (or lowered or reduced).

During the integration time EIT, the AF reset control signal RS_AF, the conversion gain control signal GCS, and the AF transfer control signal TG_AF may have the on level. The second and fourth transfer transistors TG12 and TG14 are turned on so that the charges generated in the second and fourth photodiodes PD12 and PD14 may be transferred to a floating diffusion region FD1. As the reset transistor RG1 and the dual conversion gain transistor DCG1 are turned on and the power supply voltage Vpix is applied to the floating diffusion region FD1 and the capacitor C1, the charges generated in the second and fourth photodiodes PD12 and PD14 may be removed (or lowered or reduced). The first and third transfer transistors TG11 and TG13 may be turned off in response to the off level of the first transfer control signal TS_L, and the charges generated in the first and third photodiodes PD11 and PD13 may be stored in the first and third photodiodes PD11 and PD13.

During the readout time RDT, the AF transfer control signal TG_AF may have the off level. The AF reset control signal RS_AF may be identical to the reset control signal RS of FIG. 5A. Therefore, in the HCG mode where the conversion gain control signal GCS has the low level, the reset level (HCG Reset) and signal level (HCG Signal) of the floating diffusion region FD1 may be read out. Before the signal level (HCG Signal) is read out, the first and third transfer transistors TG11 and TG13 are turned on in response to the on level of the first transfer control signal TS_L to transfer the charges stored in the first and third photo diodes PD11 and PD13 to the floating diffusion region FD1, so that the signal level (HCG Signal) of the floating diffusion region FD1 can correspond to the charge generated and stored in the first and third photo diodes PD11 and PD13.

In the LOFIC mode where the conversion gain control signal GCS has the high level, the reset level (LOFIC Reset) and a signal level (LOFIC Signal) of the floating diffusion region FD1 may be read out. Before the signal level (LOFIC Signal) is read out, the first and third transfer transistors TG11 and TG13 are turned on in response to the on level of the first transfer control signal TS_L, so that the remaining charges and newly generated charges in the first and third photodiodes PD11 and PD13 may be transferred to the floating diffusion region FD1. The signal level (LOFIC Signal) of the floating diffusion region FD1 may correspond to the charges generated and stored in the first and third photodiodes PD11 and PD13.

The readout circuit 130 (of FIG. 1) may generate pixel data representing phase information (hereinafter referred to as phase pixel data) based on the reset level and signal level read out in the LOFIC mode.

In some example embodiments, the readout circuit 130 (of FIG. 1) may generate the phase pixel data based on the reset level and the signal level read out in the LOFIC mode in a high-light environment, and may generate the phase pixel data based on the reset level and the signal level read out in the HCG mode in a low-light environment.

The auto focus pixel PX_AF described with reference to FIGS. 4 and 5B corresponds to the first auto focus pixel PX_AF1 described with reference to FIG. 3, and may generate a first phase signal representing the first phase information (e.g., left phase information) based on charges generated from the first and third photodiodes PD11 and PD13 arranged within the first region.

In the first operation mode of the second auto focus pixel PX_AF2 described with reference to FIG. 3, the first and third transfer transistors TG11 and TG13 may operate in response to the AF transfer control signal TS_AF, and the second and fourth transfer transistors TG12 and TG14 may operate in response to the second transfer control signal TS_R. The second auto focus pixel PX_AF2 may generate a second phase signal representing the second phase information (e.g., right phase information) based on charges generated from the second and fourth photodiodes PD12 and PD14 arranged within the second region.

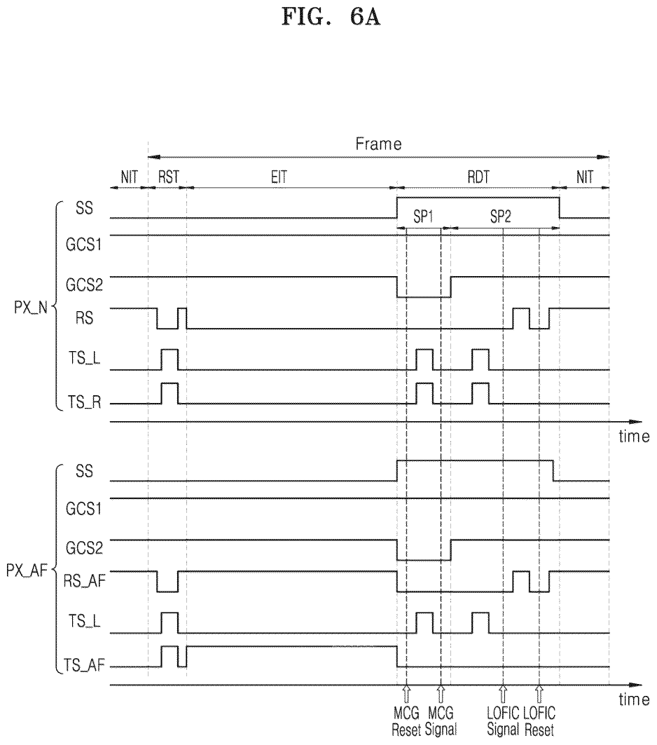

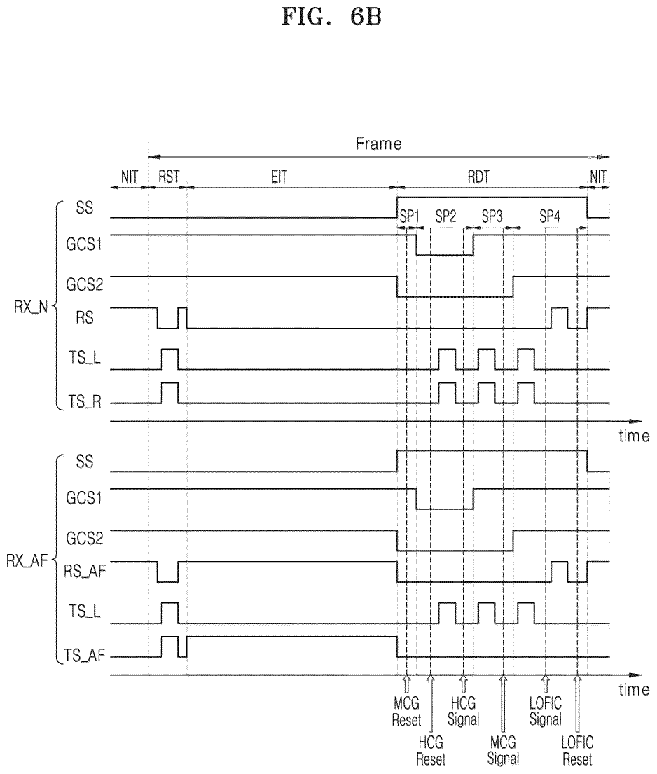

FIGS. 6A and 6B illustrate timing diagrams of a pixel array according to some example embodiments.

FIGS. 6A and 6B illustrate timing diagrams according to example embodiments of cases where the pixel PXb having the triple conversion gain of FIG. 2B is used as the normal pixel PX_N and the auto focus pixel PX_AF.

FIG. 6A is a timing diagram of some example embodiments in which the pixel array operates in the dual conversion gain mode including the MCG mode and the LCG mode during the readout time in the first operation mode.

Referring to FIG. 6A, waveforms of the control signals provided to the normal pixel PX_N are similar to the waveforms of the control signals of FIG. 5A, and the waveforms of the control signals applied to the auto focus pixel PX_AF are similar to the waveforms of the control signals of FIG. 5B. During the reset time RST, the plurality of transfer transistors TG21 to TG24 of the normal pixel PX_N are turned on in response to the on levels of the first transfer control signal TS_L and the second transfer control signal TS_R, so that the charges remaining in the first to fourth photodiodes PD21 to PD24 may be removed (or lowered or reduced), and the plurality of transfer transistors TG11 to TG14 of the auto focus pixel PX_AF are turned on in response to the on levels of the first transfer control signal TS_L and the AF transfer control signal TS_AF, so that the charges remaining in the first to fourth photodiodes PD11 to PD14 may be removed (or lowered or reduced).

During the integration time EIT, the dual conversion gain transistor DCG and the triple conversion gain transistor TCG of the normal pixel PX_N and the auto focus pixel PX_AF may be turned on in response to the on levels of the first and second conversion gain control signals GCS1 and GCS2.

The reset transistor RG of the normal pixel PX_N and the plurality of transfer transistors TG11 to TG14 may be turned off in response to the off levels of the reset control signal RS and the first and second transfer control signals TS_L and TS_R. During the integration time EIT, the plurality of photodiodes PD1 to PD4 of the normal pixel PX_N generate and store charges, and the overflowed charges may be stored in the first and second floating diffusion regions FD_1 and FD_2 and the capacitor C.

The transfer transistors (e.g., TG1 and TG3) connected to the photodiodes (e.g., the first and third photodiodes PD1 and PD3) arranged within the first region of the auto focus pixel PX_AF may be turned on in response to the off level of the first transfer control signal TS_L, and the transfer transistors (e.g., TG2 and TG4) connected to the reset transistor RG of the auto focus pixel PX_AF and the photodiodes (e.g., the second and fourth photodiodes PD2 and PD4) arranged within the second region may be turned on in response to the on levels of the AF reset control signal RS_AF and the AF transfer control signal TS_AF. During the integration time EIT, the plurality of photodiodes PD1 to PD4 of the auto focus pixel PX_AF may generate charges. Among the plurality of photodiodes, the photodiodes arranged within the first region may store the generated charges, but the charges generated in the photodiodes arranged within the second region may be removed (or lowered or reduced), and also charges overflowing from the photodiodes arranged within the first region may be removed (or lowered or reduced). In the auto focus pixel PX_AF, the charges (e.g., only the charges) generated from the photodiodes placed in the first region remain.

During the readout period, the first conversion gain control signal GCS1 may have the on level. The second conversion gain control signal GCS2 may have an off level during the first sub-period SP1 and an on level during the second sub-period SP2. Accordingly, the normal pixel PX_N and the auto focus pixel PX_AF may operate in the MCG mode during the first sub-period SP1 and in the LOFIC mode (e.g., LCG mode) during the second sub-period SP2.

The readout circuit 130 (of FIG. 1) may generate MCG pixel data representing image information based on the reset level (MCG Reset) and the signal level (MCG Signal) of the normal pixel PX_N read out in the MCG mode, and may generate LCG pixel data representing image information based on the reset level and the signal level of the normal pixel PX_N read out in the LOFIC mode. The signal processing circuit 150 of FIG. 1 (or an external processor) may generate HDR image data by merging the MCG image data including a plurality of MCG pixel data generated in the MCG mode and LCG image data including the plurality of LCG pixel data generated in the LOFIC mode.

The readout circuit 130 (of FIG. 1) may generate the pixel data (hereinafter referred to as the phase pixel data) representing the phase information based on the reset level (LOFIC Reset) and the signal level (LOFIG Signal) of the auto focus pixel PX_AF read out in the LOFIC mode. In some example embodiments, the readout circuit 130 (of FIG. 1) may generate phase pixel data based on the reset level (MCG Reset) and the signal level (MCG Signal) read out in the MCG mode in a low-light environment.

FIG. 6B is a timing diagram of some example embodiments in which the pixel array operates in the triple conversion gain mode including the HCG mode, the MCG mode and the LCG mode during the readout time in the first operation mode. Waveforms of the control signals at the reset time RST and the integration time EIT of FIG. 6B are identical or similar to the waveforms of the control signals at the reset time RST and the integration time EIT of FIG. 5B. Accordingly, redundant descriptions will be omitted, and descriptions will be provided regarding the readout time.

The leadout time may include first to fourth sub-periods SP1 to SP4. In the first sub-period SP1 and the third sub-period SP3, the first transfer control signal GCS1 may have the on level, the second transfer control signal GCS2 may have the off level, and the normal pixel PX_N and the auto focus pixel PX_AF may operate in the MCG mode. In the second sub-period SP2, the first transfer control signal GCS1 and the second transfer control signal GCS2 may have the off level, and the normal pixel PX_N and the auto focus pixel PX_AF may operate in the HCG mode. In the fourth sub-period SP4, the first and second transfer control signals GCS1 and GCS2 may have the on levels, and the normal pixel PX_N and the auto focus pixel PX_AF may operate in the LOFIC mode (e.g., LCG mode).

In the first sub-period SP1, a MCG reset level (MCG Reset) may be read out, in the second sub-period SP2, an HCG reset level (HCG Reset) and an HCG signal level (HCG Signal) may be read out, and in the third sub-period SP3, an MCG signal level (MCG Signal) may be read out. Thereafter, during the fourth sub-period SP4, a LOFIC signal level (LOFIC Signal) and a LOFIC reset level (LOFIC Reset) may be read out.

The readout circuit 130 (of FIG. 1) may generate HCG pixel data based on the reset level (HCG Reset) and the signal level (HCG Signal) of the normal pixel PX_N read out in the HCG mode, generate MCG pixel data based on the reset level (MCG Reset) and the signal level (MCG Signal) of the normal pixel PX_N read out in the MCG mode, and generate LCG pixel data based on the reset level (LOFIC Reset) and the signal level (LOFIC Signal) of the normal pixel PX_N read out in the LOFIC mode.

The signal processing circuit 150 of FIG. 1 (or an external processor) may generate HDR image data by merging the HCG image data, the MCG image data, and the LCG image data. The HCG image data includes the plurality of HCG pixel data generated in the HCG mode, MCG image data includes a plurality of MCG pixel data generated in the MCG mode, and the LCG image data includes the plurality of LCG pixel data generated in LOFIC mode. The luminance of the HCG image data, the MCG image data, and the LCG image data may be different.

The readout circuit 130 (of FIG. 1) may generate the pixel data (hereinafter referred to as the phase pixel data) representing the phase information based on the reset level (LOFIC Reset) and the signal level (LOFIC Signal) of the auto focus pixel PX_AF read out in LOFIC mode. In some example embodiments, the readout circuit 130 (of FIG. 1) may generate the phase pixel data based on the reset level (MCG Reset) and the signal level (MCG Signal) read out in the MCG mode, or may generate the phase pixel data based on the reset level (HCG Reset) and the signal level (HCG Signal) read out in the HCG mode, depending on an ambient illumination of the image sensor 100.

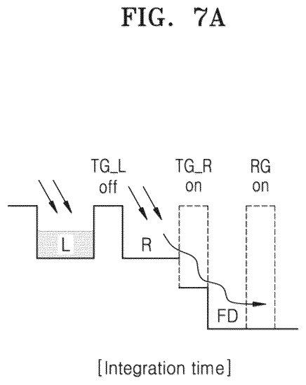

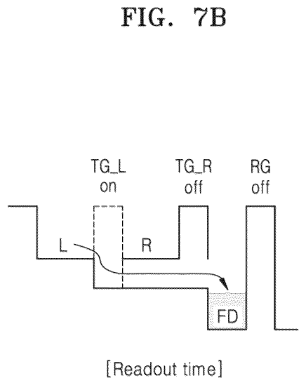

FIGS. 7A and 7B conceptually illustrate operations of autofocus pixels according to some example embodiments.

FIG. 7A illustrates a flow of charges generated in the autofocus pixel during the integration time EIT, and FIG. 7B illustrates a flow of charges generated in the auto focus pixel during the readout time RDT. The left photodiode L represents the photodiodes arranged within the first region of the autofocus pixel, and the right photodiode R represents the photodiodes arranged within the second region of the auto focus pixel. A left transfer transistor TG_L represents a transfer transistor connected to the left photodiode L, and a right transfer transistor TG_R represents a transfer transistor connected to the right photodiode R. For example, in the auto focus pixel PX_AF of FIG. 4, the left photodiode L may represent the first and third photodiodes PD11 and PD13, the right photodiode R may represent the second and fourth photodiodes PD12 and PD14, the left transfer transistor TG_L may represent the first and third transfer transistors TG11 and TG13, and the right transfer transistor TG_R may represent the second and fourth transfer transistors TG12 and TG14.

Referring to FIG. 7A, during the integration time EIT, the left photodiode L and the right photodiode R may convert received optical signals into charges, respectively. The left transfer transistor TG_L is in the off state, and the charges generated in the left photodiode L by a potential barrier of the left transfer transistor TG_L may be stored (integrated) in the left photodiode L. The right transfer transistor TG_R is in the on state, a potential barrier of the right transfer transistor TG_R is lowered so that charges generated in the right photodiode PD_R may be transferred to the floating diffusion region FD. Because the reset transistor RG is in the on state, a potential barrier of the reset transistor RG is lowered, and the power supply voltage Vpix may be applied to the floating diffusion region FD. Accordingly, the charges generated in the right photodiode R may be removed (or lowered or reduced). The charges generated from the right photodiode R may correspond to the right phase information, and the right phase information may be discarded.

Referring to FIG. 7B, during the readout time RDT, the charges stored in the left photodiode L during the integration time EIT may be transferred to the floating diffusion region FD. The left transfer transistor TG_L is in the on state, the potential barrier of the right transfer transistor TG_R is lowered so that charges generated in the right photodiode PD_R may be transferred to the floating diffusion region FD. Because the charges generated in the right photodiode R during the integration time EIT are removed (or lowered or reduced), the charges generated in the left photodiode L among the left photodiode L and the right photodiode R may be stored in the floating diffusion region FD. The charges stored in the floating diffusion region FD correspond to the left phase information, and the left phase information may be obtained as a voltage (e.g., reset level and signal level) of the floating diffusion region FD may be read out.

As described with reference to FIGS. 1 to 7B, when the image sensor 100 according to some example embodiments operates in the first operation mode, in order to prevent or limit phase information from being lost in the auto focus pixel PX_AF, the auto focus pixel PX_AF may be controlled separately from the normal pixel PX_N based on the separate control signal during the exposure time and the readout time, and the charges generated in one or more photodiodes arranged within one region (for example, the first region) among the photodiodes arranged within the first region and the second region of the auto focus pixel PX_AF may be removed (or lowered or reduced) during the exposure time, and the pixel signal including the phase information may be output based on charges generated in one or more photodiodes arranged within the other region (for example, the second region) during the readout time.

When the auto focus pixel PX_AF generates the phase detection signal according to the separate readout method different from the readout method of the normal pixel PX_N at the separate readout time, a frame rate of the image sensor may decrease as the overall readout time increases. Alternatively, when the image sensor includes autofocus-only pixels in which metal shields are placed on top of photodiodes arranged within specific regions among the photodiodes, and the autofocus-only pixels output pixel signals including phase information, the autofocus-only pixels may be processed as a bad pixel when generating image data, and bad pixel compensation is required in all operation modes of the image sensor, which may degrade the image quality.

However, the image sensor 100, when operated in the first operation mode without having the separate read-out time for generating the phase detection signal or without having the metal shields, may remove (or lower or reduce) charges generated in photodiodes arranged within one region among the photodiodes of the auto focus pixels at the exposure time and generate the phase information signal based on charges generated in the photodiodes arranged within another region at the same read-out time as the read-out time of the normal pixel PX_N. Accordingly, the separate readout time for generating the phase detection signals may not be required, so the phase detection signals may be generated without reducing a frame rate. Additionally, when the image sensor 100 operates in other operation modes (e.g., the second operation mode), the auto focus pixel may operate identically to the normal pixel based on the same control signal, and may generate the image signal as well as the phase detection signal. As a result, bad pixels do not occur in the other operation modes, which may improve image quality of image data.

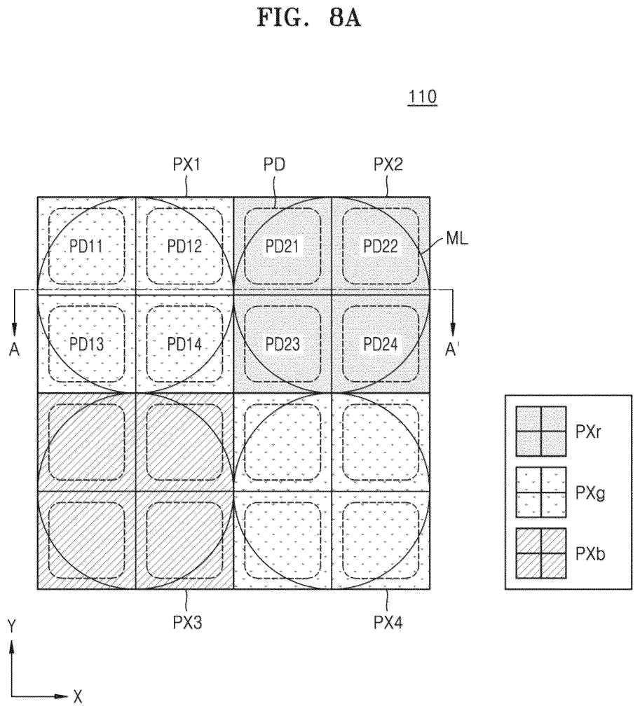

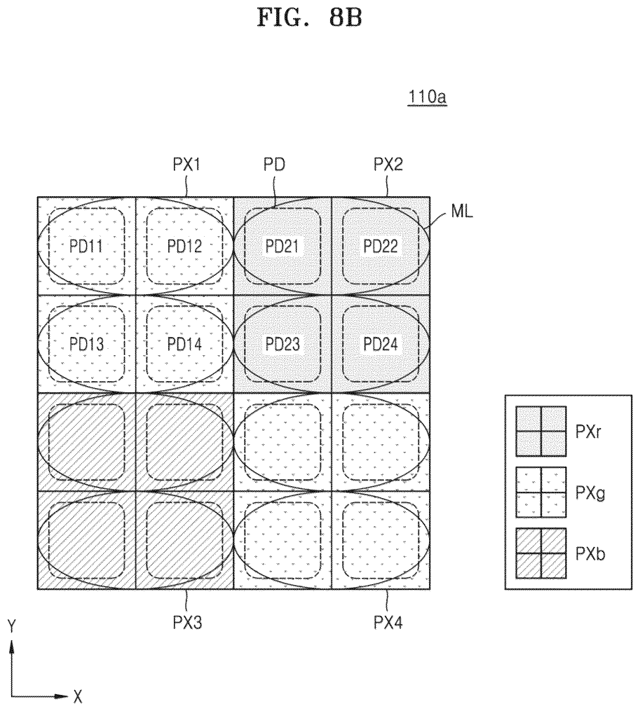

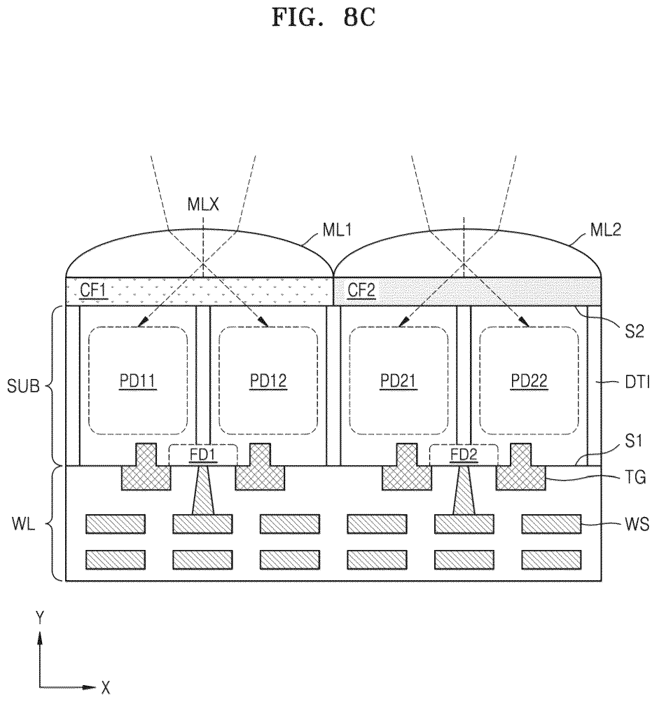

FIGS. 8A, 8B, and 8C illustrate pixel arrays according to some example embodiments. For convenience of explanation, pixel arrays 110 and 110a are illustrated as including a single pixel group including a red pixel PXr, a blue pixel PXb, and two green pixels PXg, but the pixel arrays 110 and 110a may include a plurality of pixel groups arranged in a matrix, and a number of the plurality of pixel groups may vary depending on a resolution of image sensor 100. FIGS. 8A and 8B are plan views of pixel arrays, and FIG. 8C is a vertical cross-sectional view of the pixel array 110 of FIG. 8A.

Referring to FIG. 8A, each of the first to fourth pixels PX1 to PX4 may include four photodiodes PDs arranged in a 2×2 matrix, and one micro lens ML may be arranged over the four photodiodes PDs. The micro lens ML may be placed over a top of each of the first to fourth pixels PX1 to PX4.

FIG. 8C illustrates the vertical cross-section of the first pixel and the second pixel PX1 and PX2 along line A-A′ of FIG. 8A. A wiring layer WL and a substrate SUB may be laminated in a third direction (e.g., Z-axis direction) perpendicular to a plane of the pixel array 110 based on the first direction (e.g., X-axis direction) and the second direction (e.g., Y-axis direction).

The substrate SUB may include a silicon wafer, a silicon on insulator SOI substrate, or a semiconductor epitaxial layer. The substrate SUB may include a first side S1 and a second side S2 which face each other. For example, the first side S1 may be referred to as a front side of the substrate SUB, and the second side S2 may be referred to as a back side of the substrate SUB. Light (optical signal) may be incident on the second side S2.

A plurality of photodiode isolation patterns DTI extending from the second side S2 of the substrate SUB toward the first side S1 may be formed in the substrate SUB, and regions in which photodiodes PD11, PD12, PD21, and PD22 are separately formed may be distinguished by each of the plurality of photodiode isolation patterns DTI. In some example embodiments, each region may be doped with an impurity of a first conductivity type (e.g., P-type), and well regions doped with an impurity of a second conductivity type (e.g., N-type) may be formed as the photodiodes PD11, PD12, PD21, and PD22. As illustrated, the photodiodes PD11, PD12, PD21, and PD22 may be arranged in a parallel manner in the first direction (e.g., X-axis direction).

The floating diffusion regions FD1 and FD2 shared by the photodiodes of each pixel may be formed between the first photodiodes PD11 and PD12 and the second photodiodes PD21 and PD22 of the first pixel PX1 and the second pixel PX2. Transfer transistors TG may be formed below the first photodiodes PD11 and PD12 and the second photodiodes PD21 and PD22. For example, the transfer transistor TG may be a vertical transfer transistor. In some example embodiments, source (or drain) terminals (not shown) of transistors (e.g., the reset transistor, the dual conversion gain transistor, the select transistor, the source follower transistor, and the transfer transistor) may be formed between the photodiodes PD11, PD12, PD21, and PD22 and the first side S1, and gate terminals of the transistors may be formed in a region where the first side S1 is in contact with the wiring layer WL. A plurality of wirings WS are formed in the wiring layer WL, and signals (e.g., pixel control signals, pixel signals) may be transmitted from and received by the transistors through the plurality of wirings WS.

Color filters CF1 and CF2 and micro lenses ML1 and ML2 may be placed over the photodiodes PD11, PD12, PD21, and PD22. The photodiodes PD11, PD12, PD21, and PD22 may be arranged in a parallel manner in the first region (e.g., the left region) and the second region (e.g., the right region) centered on an optical axis MLX of the micro lenses ML1 and ML2. The photodiodes PD11 and PD12 arranged within the first region may receive a first optical signal incident through the right side of the micro lenses ML1 and ML2, and the photodiodes PD21 and PD22 arranged within the second region can receive a second optical signal incident through the left side of the micro lenses ML1 and ML2. In an imaging device equipped with the image sensor 100, when an objective lens is not in focus, phases of the first optical signal and the second optical signal are different, and accordingly, the intensity of the first optical signal and the intensity of the second optical signal received at the pixel PX may be different. The amount of charges generated from the photodiodes PD11 and PD21 arranged within the first region may correspond to the intensity of the first optical signal, and the amount of charges generated from the photodiodes PD12 and PD22 arranged within the second region may correspond to the intensity of the second optical signal.

Continuing with reference to FIG. 8A, the first phase information signal may be generated based on charges generated from photodiodes arranged within the first region (e.g., the first and third photodiodes PD11 and PD13 of the first pixel PX1), and the second phase information signal may be generated based on charges generated from photodiodes arranged within the second region (e.g., the second and fourth photodiodes PD12 and PD14 of the first pixel PX1). When the image sensor 100 operates in the first operation mode, charges generated from the photodiodes placed in the first area and charges generated from the photodiodes placed in the second area may be mixed in the normal pixels. However, in the auto focus pixel, the charges generated in the photodiodes arranged within the second region or the charges generated in the photodiodes arranged within the first region may be removed (or lowered or reduced). Accordingly, the first phase information signal or the second phase information signal may be generated from the auto focus pixel. For example, the first phase information signal may be generated from the first auto focus pixel, and the second phase information signal may be generated from the second auto focus pixel.

Referring to FIG. 8B, each of the first to fourth pixels PX1 to PX4 may include four photodiodes PDs arranged in a 2×2 matrix, and one micro lens ML may be arranged on a pair of photodiodes PDs arranged in each of the first and second regions. For example, the micro lens ML may be placed over the first and second photodiodes PD11 and PD12 of the first pixel PX1, and the micro lens ML may be placed on the third and fourth photo diodes PD13 and PD14 of the first pixel PX1.

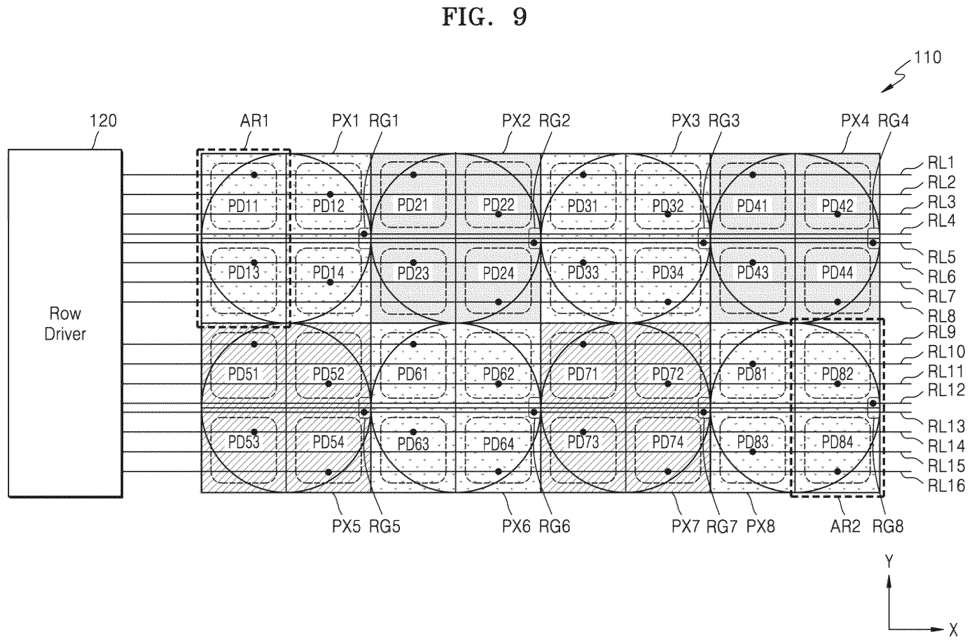

FIG. 9 illustrates connection relationships between row lines and transistors in a pixel array according to some example embodiments.

The pixel array 110 may include first to eighth pixels PX1 to PX8 arranged in a 2×4 matrix (2 rows and 4 columns), and each pixel includes four photodiodes arranged in a 2×2 matrix. As an example, the first pixel PX1 may generate first phase detection signals based on charges generated from the photodiodes PD11 and PD13 arranged within the first region AR1, and the eighth pixel PX8 may generate second phase detection signals based on charges generated from photodiodes PD82 and PD84 arranged within the second region AR2. The black dots on row lines RL1 to RL16 represent connections between the row lines and transistors (the reset transistors or the transfer transistors corresponding to the photodiodes). For convenience of explanation, the row lines RL1 to RL16 connected to the reset transistors and the transfer transistors of the first to eighth pixels PX1 to PX8 are illustrated, but the pixel array 110 may further include additional row lines connected to other transistors (e.g., the dual conversion gain transistors, the select transistors) of the first to eighth pixels PX1 to PX8.

Referring to FIG. 9, the plurality of pixels PX1 to PX8 may receive the transfer control signals and the reset control signals from the row driver 120 through the connected row lines among the plurality of row lines RL1 to RL16.

Among the first to fourth pixels PX1 to PX4 arranged in a first row, the first pixel PX1 may serve, operate, or otherwise be configured as a first auto focus pixel, and the second to fourth pixels PX2 to PX4 may respectively serve, operate, or otherwise be configured as normal pixels. The transfer transistors connected to the photodiodes arranged at the same positions within the pixels in the second to fourth pixels PX2 to PX4 may be connected to the same row lines (e.g., RL1, RL3, RL6 and RL8), and reset transistors RG2 and RG4 of the second to fourth pixels PX2 to PX4 may be connected to the same row line (e.g., RL5).

The transfer transistors connected to the first and third photodiodes PD11 and PD13 arranged within the first region AR1 of the first pixel PX1 may be connected to the first row line RL1 and the sixth row line RL6, so that the first row line RL1 and the sixth row line RL6 may be shared with the second to fourth pixels PX2 to PX4. The photodiodes PD12 and PD14 and reset transistor RG1 arranged within the second region of the first pixel PX1 may be connected to separate row lines RL2, RL4, and RL7.

Among the fifth to eighth pixels PX5 to PX8 arranged in the second row, the eighth pixel PX8 may serve, operate, or otherwise be configured as a second auto focus pixel, and the fifth to seventh pixels PX5 to PX7 may respectively serve, operate, or otherwise be configured as normal pixels. The transfer transistors connected to the photodiodes arranged at the same positions within the pixels in the fifth to seventh pixels PX5 to PX7 may be connected to the same row lines (e.g., RL9, RL11, RL14, and RL16), and the reset transistors RG5 to RG7 of the fifth to seventh pixels PX5 to PX7 may be connected to the same row line (e.g., RL13).

The transfer transistors connected to the photodiodes PD82 and PD84 arranged within the second region AR2 in the eighth pixel PX8 may be connected to the eleventh row line RL11 and the sixteenth row line RL16, so that the eleventh row line RL11 and the sixteenth row line RL16 may be shared with the fifth to seventh pixels PX5 to PX7. Photodiodes PD81 and PD83 and a reset transistor RG8 arranged within the first region of the eighth pixel PX8 may be connected to separate row lines RL10, RL12, and RL15.

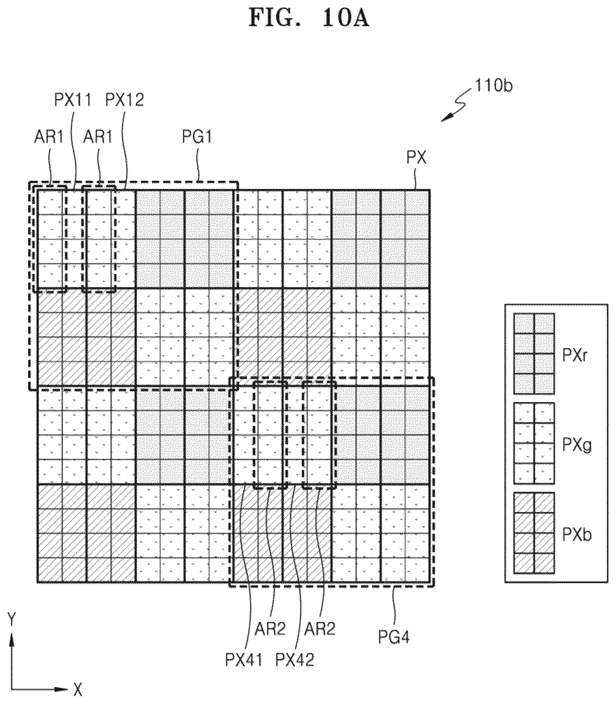

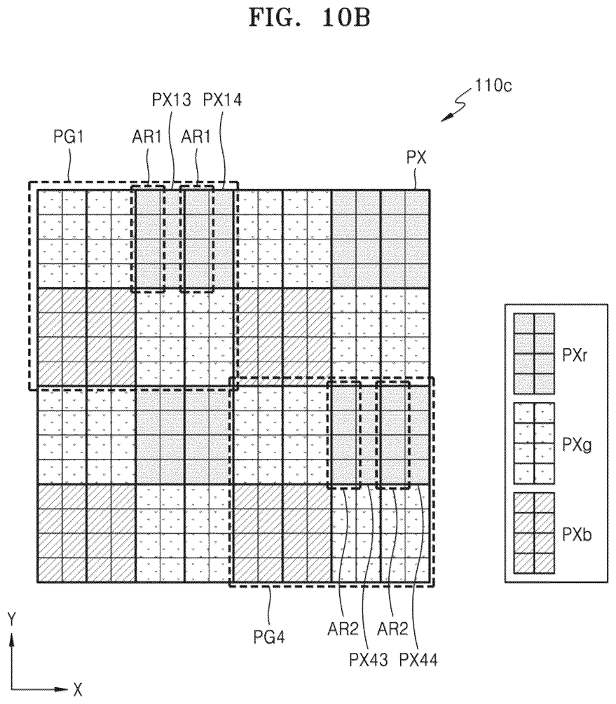

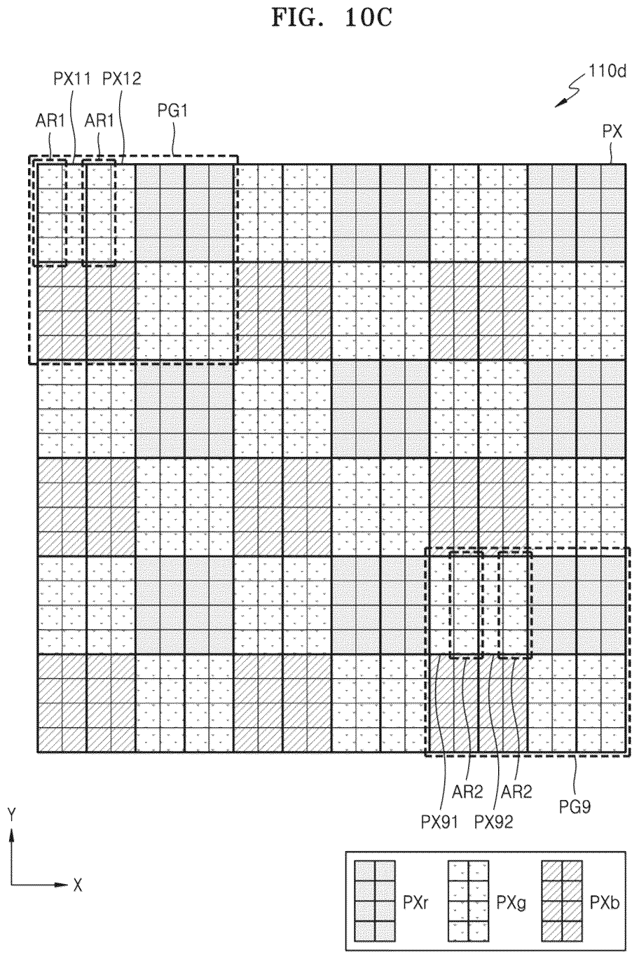

FIGS. 10A, 10B and 10C illustrate pixel arrays 110b, 110c, 110d according to some example embodiments.

Referring to FIG. 10A, in the pixel array 110b, the pixel PX may include eight photodiodes arranged in a 4×2 (4 rows and 2 columns) configuration, and two pixels PX adjacent in the first direction (e.g., in the X-axis direction) may be of an identical color. Pixel groups (e.g., PG1 and PG4) may include two red pixels PXr, two blue pixels PXb, and four green pixels PXg arranged in two rows and four columns.

In the first pixel group PG1, a first pixel PX11 and a second pixel PX12 of an identical color and adjacent to each other may serve, operate, or otherwise be configured as a first auto focus pixel, and a first phase detection signal may be generated based on charges generated in photodiodes arranged in the first region AR1 (e.g., the left region) of the first pixel PX11 and the second pixel PX12 of the first pixel group PG1. In the first pixel group PG1, a first pixel PX11 and a second pixel PX12 of an identical color and adjacent to each other may serve, operate, or otherwise be configured as a first auto focus pixel, and first phase detection signals may be generated based on charges generated in photodiodes arranged in the first region AR1 (e.g., the left region) of the first pixel PX11 and the second pixel PX12 of the first pixel group PG1.

In FIG. 10A, the green pixels PXg arranged in the same row as the red pixel PXr are described as an example of the auto focus pixels, but example embodiments are not limited thereto, and pixels of other colors may also be implemented or configured as the auto focus pixels.

Referring to FIG. 10B, in the pixel array 110c, third and fourth pixels PX13 and PX14, which are the red pixels PXr of the first pixel group PG1, may be implemented or configured as first auto focus pixels, and third and fourth pixels PX43 and PX44, which are red pixels PXr of the fourth pixel group PG4, may be implemented or configured as second auto focus pixels.

Referring to FIG. 10C, in a pixel array 110d, the auto focus pixels may be arranged in non-adjacent pixel groups (e.g., PG1 and PG9). For example, in the first pixel group PG1, first and second pixels PX11 and PX12, which are of an identical color and adjacent to each other, may respectively serve as first auto focus pixels, and in a ninth pixel group PG9 that is not adjacent to the first pixel group PG1, first and second pixels PX91 and PX92, which are of an identical color and adjacent to each other, may respectively serve as second auto focus pixels.

The pixel signal read out from the auto focus pixel is the phase detection signal including the phase information, but an image signal including the image information is not generated from the auto focus pixel. Therefore, when generating image data, image pixel data corresponding to the auto focus pixel may be generated by performing bad pixel correction based on pixel data of surrounding pixels having an identical color to the auto focus pixel. When the auto focus pixels are placed in adjacent pixel groups, the bad pixel correction may not be performed effectively. Therefore, the auto focus pixels may be placed in pixel groups that are not adjacent to each other.

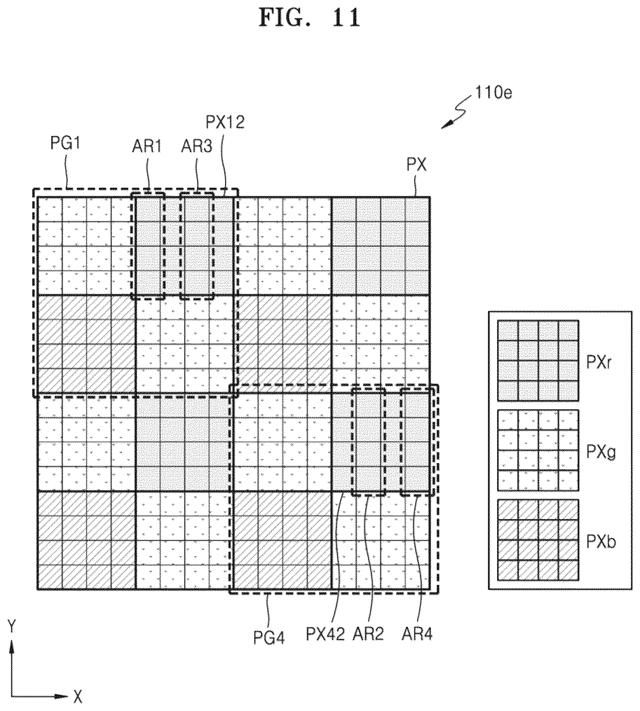

FIG. 11 illustrates a pixel array 110e according to some example embodiments.

Referring to FIG. 11, the pixel PX of the pixel array 110e may include 16 photodiodes arranged in a 4×4 (4 rows and 4 columns) configuration. Micro lenses may be arranged over at least one pair of photo diodes arranged in the first and second rows, and micro lenses may be arranged over at least one pair of photo diodes arranged in the third and fourth rows. Each of the pixel groups (e.g., PG1 and PG4) may include one red pixel PXr, one blue pixel PXb, and two green pixels PXg arranged in two rows and two columns.

In the first pixel group PG1, the second pixel PX12 may serve, operate, or otherwise be configured as the first auto focus pixel, and first phase detection signals may be generated based on charges generated from photodiodes arranged in the first region and the third region AR1 and AR3 (e.g., the first and third columns). In the fourth pixel group PG4, the second pixel PX42 may serve, operate, or otherwise be configured as a second auto focus pixel, and second phase detection signals may be generated based on charges generated in photodiodes arranged in the second and fourth regions AR2 and AR4 (e.g., the second and fourth columns) of the second pixel PX42 of the fourth pixel group PG4.

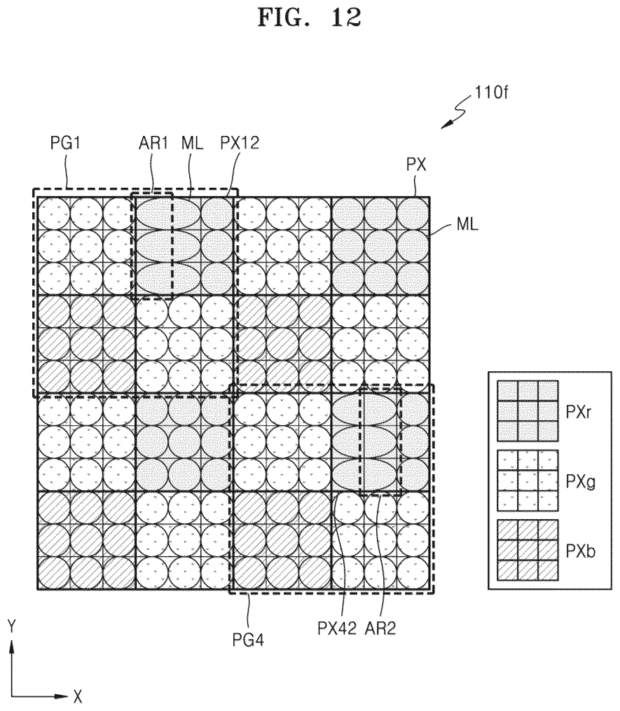

FIG. 12 illustrates a pixel array 110f according to some example embodiments.

Referring to FIG. 12, a pixel PX of the pixel array 110f may include nine photodiodes arranged in a 3×3 (3 rows and 3 columns) configuration. Each of the pixel groups (e.g., PG1 and PG4) may include one red pixel PXr, one blue pixel PXb, and two green pixels PXg arranged in two rows and two columns.

A micro lens ML may be placed over each of the photodiodes. However, a micro lens may be placed on a pair of the photodiodes arranged in the first and second rows in the second pixels PX12 and PX42 of the first pixel group PG1 and the fourth pixel group PG4.

In the first pixel group PG1, the second pixel PX12 may serve, operate, or otherwise be configured as a first auto focus pixel, and first phase detection signals may be generated based on charges generated from the photodiodes arranged in the first region AR1 (e.g., the first column). In the fourth pixel group PG4, a second pixel PX42 may serve, operate, or otherwise be configured as a second auto focus pixel, and second phase detection signals may be generated based on charges generated in the photodiodes arranged in the second region AR2 (e.g., a second column) of the second pixel PX42 of the fourth pixel group PG4.

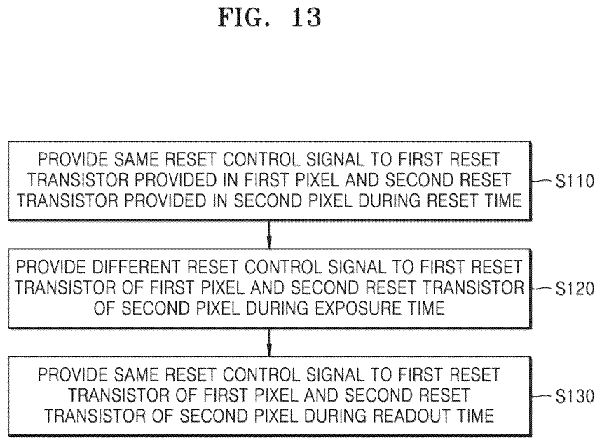

FIG. 13 is a flowchart of an operation method of an image sensor according to some example embodiments. The method of FIG. 13 represents the operation of the image sensor 100 of FIG. 1 and the pixel array 110 of FIG. 4 in the first operation mode. This will be explained with reference to FIG. 1 and FIG. 4 together.

A frame may include a reset time, an exposure time, and a readout time, and during the reset time, the same reset control signal may be provided to the first reset transistor RG1 provided in the first pixel PX_AF and the second reset transistor RG2 provided in the second pixel PX_N (S110).

During the exposure time, different reset control signals may be provided to the first reset transistor RG1 of the first pixel PX_AF and the second reset transistor RG2 of the second pixel PX_N (S120). The first pixel PX_AF and the second pixel PX_N may receive the reset control signals from the row driver 120 through different row lines, and the first pixel PX_AF may receive the first reset control signals and the second pixel PX_N may receive the second reset control signals. The first reset control signal may be a reset control signal for auto focus.

During the exposure time, the first reset control signal may be maintained at the on level (or referred to as the active level), and the second reset control signal may be maintained at the off level (or referred to as the inactive level). The second reset transistor RG2 of the second pixel PX_N may be turned off in response to the off level of the second reset control signal. The first reset transistor RG1 of the first pixel PX_AF may be turned on in response to the on level of the first reset control signal to apply the power supply voltage to the floating diffusion region FD1 and the capacitor C1 of the first pixel PX_AF.

The same transfer control signal may be provided to the first and third transfer transistors TG11, TG13, TG21, and TG23 of the first pixel PX_AF and the second pixel PX_N and the second and fourth transfer transistors TG22 and TG24 of the second pixel PX_N, and the AF transfer control signal for auto focus may be provided to the second and fourth transfer transistors TG12 and TG14 of the first pixel PX_AF.

During the exposure time, the first and third transfer transistors TG11, TG13, TG21, and TG23 of the first pixel PX_AF and the second pixel PX_N and the second and fourth transfer transistors TG22 and TG24 of the second pixel PX_N may be turned off in response to a transfer control signal of the off level, and the second and fourth transfer transistors TG12 and TG14 of the first pixel PX_AF may be turned on in response to the AF transfer control signal of the on-level. Accordingly, the charges generated in the second and fourth photodiodes PD12 and PD14 of the first pixel PX_AF are transferred to the floating diffusion region FD1, and as described above, because the power supply voltage is applied to the floating diffusion region FD1 and the capacitor C1 during the exposure time, the charges generated in the second and fourth photodiodes PD12 and PD14 may be removed (or lowered or reduced).

The charges generated in the first to fourth photodiodes PD21 to PD24 of the second pixel PX_N may overflow and be stored in the floating diffusion region FD2 and the capacitor C2. The charges generated in the first and third photodiodes PD11 and PD13 of the first pixel PX_AF may overflow into the floating diffusion region FD1, but since the power supply voltage is applied to the floating diffusion region FD1 and the capacitor C1 during the exposure time, the overflow charges may be eliminated, lowered, or reduced.

During the readout time, the same reset control signal may be provided to the first reset transistor of the first pixel PX_AF and the second reset transistor of the second pixel PX_N (S120). During the first sub-period SP1 of the read-out time, the reset control signal is maintained at the off level, and during the second sub-period SP2, after the signal level has been read out and before the reset level is read out, the reset control signal toggles from the OFF level to the on level, so that the floating diffusion regions FD1 and FD2 and capacitors C1 and C2 of the first pixel PX_AF and the second pixel PX_N may be reset.

In response to the off level of the conversion gain control signal during the first sub-period SP1 of the readout time, the dual conversion gain transistors DCG1 and DCG2 of the first pixel PX_AF and the second pixel PX_N may be turned off, and the first pixel PX_AF and the second pixel PX_N may operate in the HCG mode. The HCG reset level and HCG signal level may be read out from each of the first pixel PX_AF and the second pixel PX_N.

In response to the on level of the conversion gain control signal during the second sub-period SP2 of the readout time, the dual conversion gain transistors DCG1 and DCG2 of the first pixel PX_AF and the second pixel PX_N are turned on, and the first pixel PX_AF and the second pixel PX_N may operate in the LOFIC mode. The LOFIC signal level and the LOFIC reset level may be read out from each of the first pixel PX_AF and the second pixel PX_N.

During the readout time, the second and fourth transfer transistors TG12 and TG14 of the first pixel PX_AF may be turned off in response to the AF transfer control signal of the off level. Therefore, the HCG signal level and the LOFIC signal level read out from the first pixel PX_AF may based on charges generated from the first and third photodiodes PD11 and PD13. The HCG signal level and LOFIC signal level read out from the second pixel PX_N may be based on charges generated from the first to fourth photodiodes PD21 to PD24. In this way, the first pixel PX_AF may generate the phase detection signal, and the second pixel PX_N may generate the image signal.

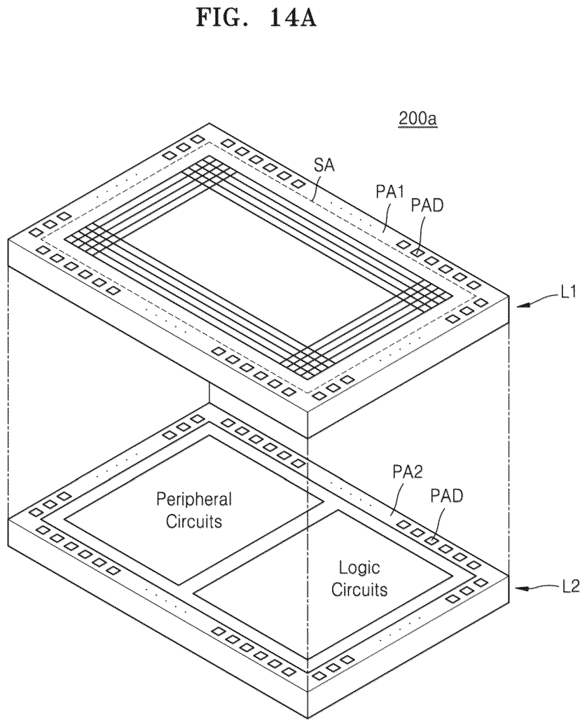

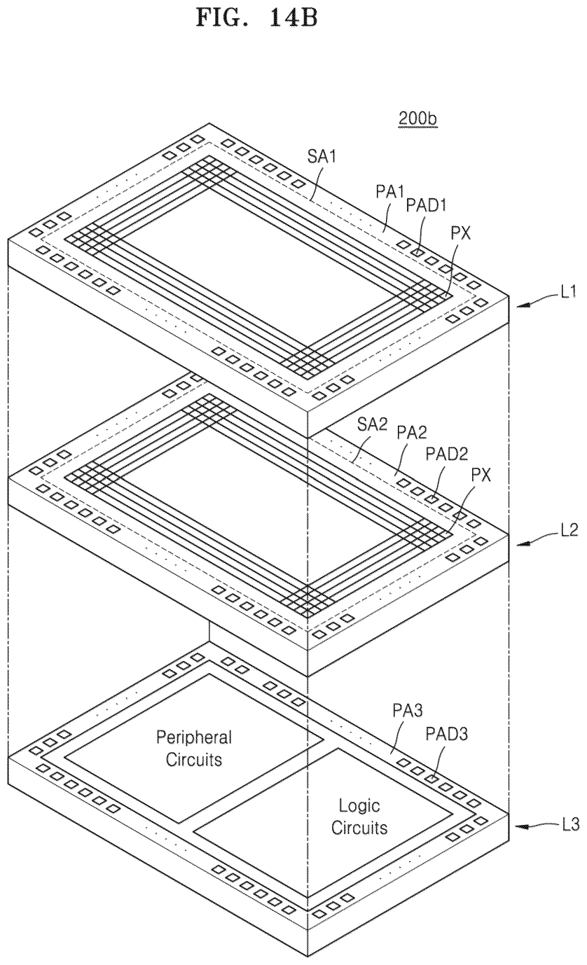

FIGS. 14A and 14B illustrate a stack structure of image sensors according to some example embodiments.

Referring to FIG. 14A, an image sensor 200A may include a plurality of stacked layers, such as a first layer L1 and a second layer L2. The first layer L1 and the second layer L2 may be manufactured by different semiconductor processes or from different semiconductor wafers. In some example embodiments, the first layer L1 and the second layer L2 may be formed on a semiconductor substrate or a semiconductor chip.

The first layer L1 may include a sensing area SA in which the plurality of pixels PX of the pixel array 110 are formed, and a first pad area PA1. A plurality of pads PAD may be arranged in the first pad area PA1, and the plurality of pads PAD of the first layer L1 may be electrically connected to the plurality of pads PAD of the second pad area PA2 of the second layer L2 through vias, contacts, etc.

Peripheral circuits and logic circuits of the image sensor 200a may be formed in the second layer L2. For example, the peripheral circuits may include the row driver 120, the readout circuit 130, the timing controller 140, and the signal processing circuit 150, as illustrated in FIG. 1.

In some example embodiments, a plurality of photodiodes and a plurality of transistors, which are provided at each pixel PX of the pixel array 110, are formed in the sensing area SA of the first layer L1, and a capacitor C, which is provided at each pixel PX, may be further formed in the second layer L2.

Referring to FIG. 14B, an image sensor 200b may include a plurality of stacked layers, for example, a first layer L1, a second layer L2, and a third layer L3. The pixel array 110 (of FIG. 1) may be formed in the first layer L1 and the second layer L2, and peripheral circuits and logic circuits may be formed in the third layer L3.

The first layer L1 may include a first sensing area SA1 in which the plurality of pixels PX of the pixel array 110 are arranged and the first pad area PA1. A plurality of pads PAD1 may be arranged in the first pad area PA1, and the plurality of pads PAD1 of the first layer L1 may be electrically connected to a plurality of pads PAD2 of the second pad area PA2 of the second layer L2 through vias, contacts, etc. In some example embodiments, the first layer L1 may be connected to the second layer L2 in a copper-copper bonding manner.

The second layer L2 may include a second sensing area SA2 in which a plurality of pixels PX are arranged and the second pad area PA2. The plurality of pads PAD2 are arranged in the second pad area PA2, and the plurality of pads PAD2 of the second layer L2 may be electrically connected to a plurality of pads PAD3 of the third layer L3 through vias, contacts, etc. The third layer L3 may include a third pad area PA3 including the plurality of pads PAD3. Peripheral circuits and logic circuits of the image sensor 200b may be formed in the third layer L3. For example, the peripheral circuits may include the row driver 120, the readout circuit 130, the timing controller 140, and the signal processing circuit 150, as illustrated in FIG. 1.

The pixel array 110 may be formed in the first sensing area SA1 of the first layer L1 and the second sensing area SA2 of the second layer L2. In some example embodiments, a plurality of photodiodes and transistors provided in each pixel PX may be formed in the first sensing area SA1 of the first layer L1, and the capacitors C provided in each pixel PX may be formed in the second sensing area SA2 of the second layer L2.

In some example embodiments, the plurality of photodiodes and the plurality of transfer transistors provided in each pixel PX of the pixel array 110 may be formed in the first sensing area SA1 of the first layer L1, and transistors (e.g., a reset transistor, a dual conversion gain transistor, a source follower transistor, and a select transistor) and the capacitor C other than the plurality of transfer transistors among the plurality of transistors provided in each pixel PX may be formed in the second sensing area SA2 of the second layer L2.

In some example embodiments, the plurality of photodiodes and the plurality of transfer transistors provided in each pixel PX are formed in the first sensing area SA1 of the first layer L1, transistors other than the plurality of transfer transistors among the plurality of transistors provided in each pixel PX may be formed in the second sensing area SA2 of the second layer L2, and the capacitors C provided in each pixel PX may be further formed in the third layer L3.

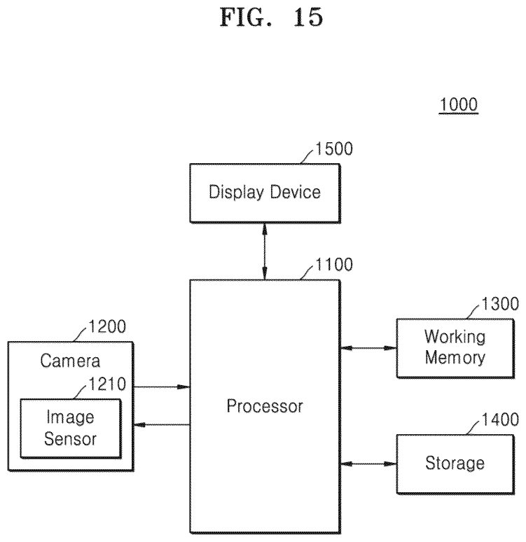

FIG. 15 is a block diagram illustrating an electronic device including an image sensor according to some example embodiments.

An electronic device 1000 is an electronic device having an image or light sensing function, and for example, the electronic device 1000 may be a portable terminal.

The electronic device 1000 may include a processor 1100, a camera module 1200, a working memory 1300, a storage 1400, and a display device 1500. The electronic device 1000 may further include other components, such as a user interface, a communication module, a sensor module, etc.

The processor 1100 may control the overall operation of the electronic device 1000 and may be implemented as a system on chip (SoC) that runs application programs, operating systems, etc. In some example embodiments, the processor 1100 may include an application processor.

The processor 1100 may provide image data provided from the camera module 1200 to the display device 1500 or store the image data in the storage 1400. In some example embodiments, the processor 1100 may have an image processing circuit, and the image processing circuit may perform image processing on image data received from the camera module 1200. For example, the image processing circuit may perform image processing such as Auto-focus correction, Auto-white balance, and Auto-exposure (3A) adjustment, sharpening, gamma control, resolution scaling (video/preview), and demosaic HDR processing.

The camera module 1200 may be an example of an image generating device and may include an image sensor 1210 and may also include an objective lens and an actuator for adjusting a focal length of the objective lens.

The image sensor 1210 may be implemented as the image sensor 100 described with reference to FIGS. 1 to 13. The image sensor 1210 may include a first pixel (e.g., an auto focus pixel) and a second pixel (e.g., a normal pixel), and each of the first pixel and the second pixel may include a plurality of photodiodes and a capacitor. When a first image sensor 1211 operates in the first operation mode, the capacitor of the second pixel stores overflowed charges from a plurality of photodiodes, and the overflowed charges stored in the capacitor may be used to generate an HDR image. At this time, the first pixel operates based on control signals that are different from the control signals provided to the second pixel (e.g., a reset control signal, a plurality of transfer control signals) to remove (or lower or reduce) charges generated in the photodiodes arranged in a second region (or a first region) and generate a phase detection signal based on charges generated in the photodiodes arranged in the first region (or the second region). The image sensor 1210 may transmit phase difference data generated based on the phase detection signal to the application processor 1100. The image sensor 1210 may support an auto focus function of the camera module 1200 without increasing the readout time in the first operation mode, and may also generate image data with improved image quality while supporting the auto focus function in other operation modes.

The image sensor 1210 may transmit the phase difference data to the application processor 1100, and the processor 1100 may calculate the focal length of the objective lens based on the phase difference data and transmit a focal length adjustment signal for adjusting the focal length of the objective lens to the camera module 1200. An actuator of the camera module 1200 may move the objective lens based on a focal length adjustment signal. In this way, autofocus based on phase difference may be performed.

The application processor 1100 may also transmit sensor control signals to the image sensor 1210 to control the operation of the image sensor 1210. The control signals may include, for example, setting values and configuration data related to an operating mode, a shuttering mode, and the like of the image sensor 1210. For example, configuration data may include exposure time settings, analog gain, digital gain, lens shading compensation values, crosstalk coefficients, frame rate settings, etc. Transmission of sensor control signals may be performed through an interface based on Inter-Integrated Circuit (I2C), for example.

The image sensor 1210 may transmit image data or signal processed image data to the processor 1100. Transmission of image data may be performed, for example, using a camera serial interface (CSI) based on the mobile industry processor interface (MIPI), but example embodiments are not limited thereto.

The working memory 1300 may be implemented as a volatile memory, such as DRAM or static random-access memory (SRAM), or as a nonvolatile resistive memory, such as ferroelectric RAM (FeRAM), resistive RAM (RRAM), or phase-change RAM (PRAM). The working memory 1300 may store programs and/or data processed or executed by the processor 1100.

The storage 1400 may be implemented as a non-volatile memory device, such as NAND flash memory (NAND flash), RRAM, and the like, and, for example, the storage 1400 may be provided as a memory card, such as a multimedia card (MMC), an embedded multimedia card (eMMC), a secure digital card (SD), or a micro secure digital card (microSD). The storage 1400 may store image data provided from the camera module 1200.

According to some example embodiments, an electronic device comprises a processor; and an image generating device communicably coupled to the processor and including an image sensor. The image sensor comprises, a pixel array including a first pixel and a second pixel, wherein the first pixel and the second pixel are in a same row, the first pixel is configured to output a phase detection signal and the second pixel is configured to output an image signal, and each of the first pixel and the second pixel comprises, a first photodiode and a second photodiode; a floating diffusion region electrically connected to the first photodiode and the second photodiode; a capacitor electrically connected to the floating diffusion region; a dual conversion gain transistor connected between the floating diffusion region and the capacitor; and a reset transistor configured to provide a power supply voltage to the floating diffusion region and the capacitor, and a row driver configured to provide a plurality of control signals to the first pixel and the second pixel through a plurality of row lines, provide a first reset control signal to a first reset transistor of the first pixel through a first row line of the plurality of row lines, and provide a second reset control signal to a second reset transistor of the second pixel through a second row line of the plurality of row lines. The image sensor is configured to generate phase difference data based on the phase detection signal and transmit the phase difference data to the processor, and the processor is configured to control an operation of the image generating device based on the phase difference data. According to some example embodiments, the image sensor further comprises: a readout circuit configured to convert a first pixel signal output from the first pixel into first pixel data, and to convert a second pixel signal received from the second pixel into second pixel data; and a signal processing circuit configured to generate phase difference data, based on the first pixel data, and to generate image data, based on the second pixel data. According to some example embodiments, in a first operation mode, during a first period, the first reset control signal has an active level and the second reset control signal has an inactive level, and during a second period following the first period, the first reset control signal and the second reset control signal have a same level. According to some example embodiments, in the first operation mode, during the first period, the capacitor of the second pixel is configured to store overflowed charges from the first photodiode and the second photodiode of the second pixel, and during the second period, the second pixel is configured to output a pixel signal that is generated based on the overflowed charges stored in the capacitor. According to some example embodiments, in a second operation mode, the first reset control signal and the second reset control signal are identical during the first period and the second period.

Example embodiments are not necessarily mutually exclusive. For example, some example embodiments may include one or more features described with reference to one or more figures, and may also include one or more other features described with reference to one or more other figures.

As described herein, any devices, systems, modules, portions, units, controllers, circuits, and/or portions thereof according to any of the example embodiments, and/or any portions thereof (including, without limitation, the pixel array 110, the row driver 120, the readout circuit 130, the timing controller 140, the signal processing circuit 150, the processor 1100, the camera module 1200, the working memory 1300, the storage 1400, the display device 1500, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), a programmable logic unit, a microprocessor, an application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. An image sensor comprising:
a pixel array including a first pixel and a second pixel, the first pixel and the second pixel being in a same row, wherein each of the first pixel and the second pixel comprises,
a first photodiode and a second photodiode;
a floating diffusion region electrically connected to the first photodiode and the second photodiode;
a capacitor electrically connected to the floating diffusion region;
a dual conversion gain transistor connected between the floating diffusion region and the capacitor; and
a reset transistor configured to provide a power supply voltage to the floating diffusion region and the capacitor, and
a row driver configured to provide a plurality of control signals to the first pixel and the second pixel through a plurality of row lines, provide a first reset control signal to a first reset transistor of the first pixel through a first row line of the plurality of row lines, and provide a second reset control signal to a second reset transistor of the second pixel through a second row line of the plurality of row lines.

2. The image sensor of claim 1, further comprising:
a readout circuit configured to convert a first pixel signal output from the first pixel into first pixel data, and to convert a second pixel signal received from the second pixel into second pixel data; and
a signal processing circuit configured to generate phase difference data, based on the first pixel data, and to generate image data, based on the second pixel data.

3. The image sensor of claim 1, wherein in a first operation mode, during a first period, the first reset control signal has an active level and the second reset control signal has an inactive level, and during a second period following the first period, the first reset control signal and the second reset control signal have a same level.

4. The image sensor of claim 3, wherein in the first operation mode, during the first period, the capacitor of the second pixel is configured to store overflowed charges from the first photodiode and the second photodiode of the second pixel, and during the second period, the second pixel is configured to output a pixel signal that is generated based on the overflowed charges stored in the capacitor.

5. The image sensor of claim 3, wherein in a second operation mode, the first reset control signal and the second reset control signal are identical during the first period and the second period.

6. The image sensor of claim 1, wherein each of the first pixel and the second pixel further comprises:
a first transfer transistor connected between the first photodiode and the floating diffusion region; and
a second transfer transistor connected between the second photodiode and the floating diffusion region, and
wherein the row driver is further configured to,
provide a first transfer control signal to the first transfer transistors of the first pixel and the second pixel through a third row line of the plurality of row lines;
provide a second transfer control signal to the second transfer transistor of the first pixel through a fourth row line of the plurality of row lines; and
provide a third transfer control signal to the second transfer transistor of the second pixel through a fifth row line of the plurality of row lines.

7. The image sensor of claim 6, wherein in a first operation mode, during a first period of a frame, the first transfer control signal and the third transfer control signal have an inactive level, and the second transfer control signal has an active level, and during a second period following the first period, the second transfer control signal has an inactive level.

8. The image sensor of claim 7, wherein, during the first period, the first photodiode is configured to store charges generated in the first photodiode of the first pixel, and the second photodiode of the first pixel is configured to reduce charges generated in the second photodiode.

9. The image sensor of claim 6, wherein in a first operation mode, the first transfer control signal and the third transfer control signal are identical, and the first transfer transistors of the first pixel and the second pixel and the second transfer transistor of the second pixel operate identically.

10. The image sensor of claim 1, further comprising:
a first micro lens over the first photodiode and the second photodiode of the first pixel, and
a second micro lens over the first photodiode and the second photodiode of the second pixel.

11. An image sensor comprising:
a pixel array including a plurality of pixel groups in a matrix, each pixel group of the plurality of pixel groups including a plurality of pixels in a matrix,
wherein each pixel of the plurality of pixels comprises,
a plurality of first photodiodes in a first region;
a plurality of second photodiodes in a second region;
a floating diffusion region electrically connected to the plurality of first photodiodes and the plurality of second photodiodes;
a capacitor electrically connected to the floating diffusion region; and
a reset transistor configured to provide a power supply voltage to the floating diffusion region and the capacitor; and
a row driver configured to provide a first reset control signal to a first reset transistor of a first pixel of the plurality of pixels, and provide a second reset control signal different from the first reset control signal to a second reset transistor of a second pixel of the plurality of pixels, the second pixel being in a same row as the first pixel.

12. The image sensor of claim 11, wherein the row driver is further configured to:
provide a plurality of control signals to the plurality of pixels through a plurality of row lines;
provide the first reset control signal to the first reset transistor through a first row line among a plurality of row lines; and
provide the second reset control signal to the second reset transistor through a second row line among the plurality of row lines.

13. The image sensor of claim 11, wherein, during an exposure period of a frame, the first reset transistor of the first pixel is turned on in response to an active level of the first reset control signal, and the second reset transistor of the second pixel is turned off in response to an inactive level of the second reset control signal.

14. The image sensor of claim 13, wherein, during the exposure period, the capacitor of the second pixel is configured to store overflowed charges from the plurality of first photodiodes and the plurality of second photodiodes of the second pixel.

15. The image sensor of claim 11, wherein each of the plurality of pixels further comprises:
a plurality of first transfer transistors; and
a plurality of second transfer transistors, each transfer transistor of the plurality of first transfer transistors and the plurality of second transfer transistors being connected between a corresponding photodiode of the plurality of first photodiodes and the plurality of second photodiodes, and the floating diffusion region, and
wherein the row driver is further configured to,
provide a first transfer control signal to the plurality of first transfer transistors of the first pixel, the plurality of first transfer transistors of the second pixel, and the plurality of second transfer transistors of the second pixel; and
provide, to the plurality of second transfer transistors of the first pixel, a second transfer control signal different from the first transfer control signal.

16. The image sensor of claim 15, wherein, during an exposure period of a frame, the first transfer control signal has an inactive level and the second transfer control signal has an active level, and
during a readout period following the exposure period, the first transfer control signal is configured to toggle between the active level and the inactive level, and the second transfer control signal has the inactive level.

17. The image sensor of claim 11, wherein each pixel group of the plurality of pixel groups includes the first pixel,
wherein the first pixel of a first pixel group of the plurality of pixel groups is configured to output a first phase detection signal based on charges by from the plurality of first photodiodes, and
wherein the first pixel of a second pixel group adjacent to the first pixel group is configured to output a second phase detection signal based on charges by from the plurality of second photodiodes.

18. An operating method of an image sensor, comprising:
providing, during an exposure time, different reset control signals through a different control line to a first reset transistor included in a first pixel of the image sensor and a second reset transistor included in a second pixel of the image sensor, the first pixel and the second pixel being in a same row, and each of the first pixel and the second pixel including a plurality of photodiodes arranged in a matrix;
providing, during a readout time following the exposure time, a same reset control signal to the first reset transistor and the second reset transistor; and
outputting a phase detection signal using the first pixel and outputting an image signal using the second pixel.

19. The operating method of claim 18, wherein the providing the different reset control signals comprises,
providing a first reset control signal having an active level to the first reset transistor; and
providing a second reset control signal having an inactive level to the second reset transistor, and
the operating method further comprises storing, during the exposure time, overflowed charges from the plurality of photodiodes of the second pixel in a capacitor included in the second pixel.

20. The operating method of claim 19, wherein the first pixel further comprises:
a first transfer transistor connected between a first photodiode among the plurality of photodiodes and a floating diffusion region, the first photodiode being in a first region; and
a second transfer transistor connected between a second photodiode among the plurality of photodiodes and the floating diffusion region, the second photodiode being in a second region, and
wherein the operating method further comprises,
providing a transfer control signal having the inactive level to the first transfer transistor of the first pixel during the exposure time; and
providing a second transfer control signal having the active level to the second transfer transistor of the first pixel during the exposure time.
